(19) United States
(12) Patent Application Publication
(10) Pub. No.: US 2026/0371899 A1
(43) Pub. Date: Nov. 19, 2026

(54) FOLDABLE APPARATUS COMPRISING GLASS-BASED LAYERS ON OPPOSING SIDES OF DISPLAY PANEL

(71) Applicant: CORNING INCORPORATED, CORNING, NY (US)

(72) Inventors: Jaymin Amin, Corning, NY (US); Balamurugan Meenakshi Sundaram, Painted Post, NY (US); Jason Thomas Harris, Horseheads, NY (US); Peter Joseph Lezzi, Corning, NY (US); Jonathan David Pesansky, Corning, NY (US); Yousef Kayed Qaroush, Horseheads, NY (US); Yaochi Wei, Pittsford, NY (US)

(21) Appl. No.: 19/675,915

(22) Filed: May 13, 2026

Related U.S. Application Data
(60) Provisional application No. 63/805,664, filed on May 14, 2025.

(51) Int. Cl. H10K 59/80; G06F 1/16; H10K 77/10; H10K 102/00

(52) U.S. Cl. CPC H10K 59/871; G06F 1/1652; H10K 77/111; H10K 59/8722; H10K 2102/311

(57) ABSTRACT

A foldable apparatus includes a first glass-based layer, an OLED display panel, and a second glass-based layer disposed such that a display substrate is disposed between the first glass-based layer and the second glass-based layer. The foldable apparatus is configured to bend at a bend axis. The foldable apparatus can be configured such that one or more of: (a) a first major surface of the second glass-based layer is disposed within 400 μm of a rear surface of the display substrate, (b) the second glass-based layer comprises a plurality of separate segments; (c) the second glass-based layer comprises a variable thickness component of glass-based material; and (d) the foldable apparatus exhibits a reduced bending-induced tensile strain as compared to a comparative foldable apparatus with the second glass-based layer removed.

This application claims the benefit of priority under 35 U.S.C. § 119 of U.S. Provisional Application Ser. No. 63/805,664 filed on May 14, 2025, the content of which is relied upon and incorporated herein by reference in its entirety.

### FIELD

The present disclosure relates generally to a foldable apparatus comprising multiple glass-based layers.

### BACKGROUND

Glass-based substrates are commonly used, for example, in display devices, for example, liquid crystal displays (LCDs), electrophoretic displays (EPD), organic light-emitting diode displays (OLEDs), plasma display panels (PDPs), or the like.

There is a desire to develop foldable versions of displays as well as foldable protective covers to mount on foldable displays. Foldable displays and covers should have good impact and puncture resistance. At the same time, foldable displays and covers should have small minimum bend radii (e.g., about 10 millimeters (mm) or less). However, plastic displays and covers with small minimum bend radii tend to have poor impact and/or puncture resistance. Furthermore, conventional wisdom suggests that ultra-thin glass-based sheets (e.g., about 75 micrometers (μm or microns) or less thick) with small minimum bend radii tend to have poor impact and/or puncture resistance. Furthermore, thicker glass-based sheets (e.g., greater than 125 micrometers) with good impact and/or puncture resistance tend to have relatively large minimum bend radii (e.g., about 30 millimeters or more). Consequently, there is a need to develop foldable apparatus that have low minimum bend radii and good impact and puncture resistance.

### SUMMARY

There are set forth herein foldable apparatus that includes a cover glass stack comprising a first glass-based layer, an OLED display panel, and a second glass-based layer disposed such that that a display substrate is disposed between the first glass-based layer and the second glass-based layer. The first glass-based layer is disposed more proximate to a user when the foldable apparatus is in an unfolded state and is bent to exhibit a higher degree of curvature when the foldable apparatus is placed in a folded state. Since the second glass-based layer is bent to a lesser extent during folding, the rigidity added by the second glass-based layer can provide a number of performance benefits without significantly impacting the bendability (quantified herein as a “minimum bend radius” and/or “parallel plate distance”) of the foldable apparatus. The second glass-based layer has the ability to recover from deformations induced by folding to a greater extent than other materials (e.g., metals, polymer-based materials) typically disposed rearward of the display substrate. The addition of the second glass-based layer is believed to provide favorable crease recovery performance, which herein is assessed as a measured optical distortion of a hinge region of the apparatus in an area around a bend axis. The second glass-based layer can also beneficially reduce the tensile strains present in the OLED display panel during bending

The first-glass-based layer is formed of a first glass-based material and is constructed to ensure that the foldable apparatus is bendable to extent suitable for the particular application of the foldable apparatus. For example, in aspects, the foldable apparatus is usable in a foldable phone or the like where, in the folded state, the first glass-based layer is bent to exhibit a minimum effective bend radius of less than or equal to 10 mm (e.g., from 1 mm to 10 mm, from 1 mm to 5 mm, from 3 mm to 5 mm). In such aspects, the first glass-based layer is an amorphous layer formed from a glass composition that exhibits a relatively low elastic modulus (e.g., less than or equal to 75 GPa), and is chemically strengthenable so as to exhibit a relatively high maximum surface compressive stress, such that the first glass-based layer exhibits a relatively high CS/E that is greater than or equal to 15. Moreover, the first glass-based layer can have a relatively low minimum thickness (also referred to herein as a “first thickness”) in a range that is greater than or equal to 10 μm and less than or equal to 50 μm. Such a combination of features counteracts bending-induced stresses on the first glass-based layer to prevent failure thereof when the foldable apparatus is placed in the folded state. In other aspects, the foldable apparatus can be used in devices (e.g., laptops or tables) where a less extreme degree of bendability is needed (e.g., to a minimum bend radius of around 100 mm). In such cases, there is more flexibility in terms of thickness and composition of the first glass-based layer.

The second glass-based layer is positioned to impart rigidity to the apparatus to thereby improve crease recovery performance over comparative apparatuses not including such an underside glass-based layer without significantly degrading bendability. In aspects, the second glass-based layer is positioned such that a first major surface thereof is positioned less than or equal to 400 μm from the display substrate. Moreover, the second glass-based layer can have a second minimum thickness (also referred to herein as a “second thickness”) such that a combined thickness of the first and second glass-based layers is greater than or equal to 30 μm and less than or equal to 150 μm. Such a second minimum thickness facilitates recovering bending-induced deformation and can also provide for favorable neutral axis positioning in the OLED display panel when the foldable apparatus is placed in the bent state. Such neutral axis positioning can prevent component failure in the OLED display panel caused by repeated bending. The second glass-based layer therefore can provide performance improvements over existing apparatuses not including such a layer without significantly impacting bendability.

Embodiments of the present disclosure can be further understood in view of the following aspects:

An aspect (1) of the present disclosure pertains to a foldable apparatus comprising: a cover glass stack comprising a first glass-based layer, the first glass-based layer comprising a first thickness that is greater than or equal to 10 μm and less than or equal to 200 μm; an OLED display panel disposed on the cover glass stack, the OLED display panel comprising a display substrate; and a second glass-based layer disposed on the OLED display panel such that the display substrate is disposed between the first glass-based layer and the second glass-based layer, the second glass-based layer comprising a second thickness that is greater than or equal to 10 μm and less than or equal to 200 μm, wherein: the cover glass stack is protective cover for the OLED display panel so that an image generated by the display is viewable through the cover glass stack, the foldable apparatus is configured to bend at a bend axis, when the foldable apparatus is maintained in a bent state for a time period of at least 24 hours so that a front surface of foldable apparatus exhibits a minimum bend radius of less than 20 mm and subsequently released, the foldable apparatus comprises a crease region, the second glass-based layer comprises a continuous volume of glass-based material with a minimum thickness of at least 10 μm within the crease region, a combined thickness of the first and second glass-based layers is greater than or equal to 30 μm, and at least one of: a first major surface of the second glass-based layer is disposed within 400 μm of a rear surface of the display substrate, the second glass-based layer comprises a plurality of segments that are separated from one another by gaps so that the second glass-based layer does not cover an entirety of the display substrate, the second glass-based layer comprises a variable thickness component of glass-based material, the second glass-based layer is a component of a laminate, the laminate comprising an additional layer of glass-based material laminated to the second glass-based layer, and the foldable apparatus when maintained at a parallel plate distance of 3 mm, exhibits a maximum tensile strain in the OLED display panel that is less than a comparative foldable apparatus having the same structure as the foldable apparatus except the comparative foldable apparatus has the second glass-based layer removed.

An aspect (2) of the present disclosure pertains to a foldable apparatus according to the aspect (1), wherein the second glass-based layer comprises the variable thickness component and the variable thickness component is the second glass-based layer, which comprises a reduced-thickness portion.

An aspect (3) of the present disclosure pertains to a foldable apparatus according to the aspect (2), wherein the reduced-thickness portion comprises a recessed area of the first major surface of the second glass-based layer facing the OLED display panel.

An aspect (4) of the present disclosure pertains to a foldable apparatus according to any of the aspects (2)-(3), wherein the reduced-thickness portion comprises a recessed area of a second major surface of the second glass-based layer facing away from the OLED display panel.

An aspect (5) of the present disclosure pertains to a foldable apparatus according to any of the aspects (2)-(4), wherein the reduced thickness portion is centered at the bend axis.

An aspect (6) of the present disclosure pertains to a foldable apparatus according to the aspect (1), wherein: the second glass-based layer comprises the plurality of segments, and the plurality of segments comprise a central segment centered on the bend axis and two or more off-center segments offset from the central segment away from the bend axis.

An aspect (7) of the present disclosure pertains to a foldable apparatus according to the aspect (6), wherein the central segment comprises a width in a direction perpendicular to the bend axis that is greater than widths of the off-center segments.

An aspect (8) of the present disclosure pertains to a foldable apparatus according to the aspect (1), wherein: the second glass-based layer comprises the plurality of segments, and none of the segments overlap the bend axis in a thickness direction of the foldable apparatus, so that the second glass-based layer does is devoid of glass-based material at the bend axis.

An aspect (9) of the present disclosure pertains to a foldable apparatus according to any of the aspects (1)-(8), wherein the cover glass stack comprises an additional layer of glass-based material attached to the first glass-based layer by a layer of optically clear adhesive.

An aspect (10) of the present disclosure pertains to a foldable apparatus according to any of the aspects (1)-(9), wherein the second glass-based layer comprises a glass ceramic.

An aspect (11) of the present disclosure pertains to a foldable apparatus according to any of the aspects (1)-(10), wherein a Young's modulus of the second glass-based layer is at least 5 GPa greater than a Young's modulus of the first glass-based layer.

An aspect (12) of the present disclosure pertains to a foldable apparatus according to any of the aspects (1)-(11), wherein the second glass-based layer comprises a thermal conductivity greater than or equal to 0.05 W*m⁻¹*K⁻¹.

An aspect (13) of the present disclosure pertains to a foldable apparatus according to any of the aspects (1)-(12), wherein the second glass-based layer exhibits an average transmittance that is greater than or equal to 70% over a wavelength range of 400 nm to 700 nm.

An aspect (14) of the present disclosure pertains to a foldable apparatus according to any of the aspects (1)-(13), wherein: both the first glass-based layer and the second glass-based layer are ion exchanged so that they have regions of compressive stress extending inward from major surfaces thereof, each of the first glass-based layer and the second glass-based layer consists of a single layer of glass-based material, and at least one of: the first glass-based layer exhibits a greater maximum compressive stress (CS) than that of the second glass-based layer, and the first glass-based layer exhibits a ratio of CS (in MPa) to Young's modulus (in GPa) that is at least 1.0 (units omitted) greater than that of the second glass-based layer.

An aspect (15) of the present disclosure pertains to a foldable apparatus according to any of the aspects (1)-(14), wherein the parallel plate distance occurs when the foldable apparatus is bent in an elliptical bend configuration.

An aspect (16) of the present disclosure pertains to a foldable apparatus according to the aspect (15), wherein: a fold plane extending perpendicular to the bend axis and perpendicular to at least a portion of a major surface of the first glass-based layer when the foldable apparatus is in an unbent state extends through glass-based material of the second glass-based layer, and after being held at the parallel plate distance for a period of 120 hours and subsequently released, a front surface of the foldable apparatus exhibits a crease height recovery of at least 40% over a 24-hour period after being released.

An aspect (17) of the present disclosure pertains to a foldable apparatus according to any of the aspects (1)-(14), wherein, when the foldable apparatus is folded in a waterdrop configuration such that unbent portions of the foldable apparatus are separated by a minimum separation distance of 1.3 mm and the foldable apparatus is maintained in the waterdrop configuration for 24 hours and subsequently released, the foldable apparatus exhibits an initial maximum optical distortion of less than 30 D when viewed from a front surface of the foldable apparatus 2 minutes after release.

An aspect (18) of the present disclosure pertains to a foldable apparatus according to the aspect (17), wherein, 24 hours after release, the foldable apparatus exhibits a second maximum optical distortion value that is less than 50% of the initial maximum optical distortion value.

An aspect (19) of the present disclosure pertains to a foldable apparatus according to any of the aspects (1)-(18), wherein the second glass-based layer comprises a composite article, the composite article comprising: a glass-based layer formed of a glass-based material; and a second layer disposed directly on the glass-based layer, the second layer comprising an elastic modulus that is at least 10 GPa greater than the glass-based layer.

An aspect (20) of the present disclosure pertains to a foldable apparatus according to the aspect (19), wherein the second layer comprises a thickness that is greater than or equal to 1 μm and less than or equal to 10 μm.

An aspect (21) of the present disclosure pertains to a foldable apparatus according to the aspect (20), wherein the thickness of the second layer is at least 2.0% of a thickness of the glass-based layer.

An aspect (22) of the present disclosure pertains to a foldable apparatus according to any of the aspects (19)-(21), wherein an overall thickness of the composite article is less than or equal to 100 μm.

An aspect (23) of the present disclosure pertains to a foldable apparatus according to any of the aspects (19)-(22), wherein the second layer comprises Al₂O₃, AlN, AlOₓN_{y}, Si₃N₄, SiOₓN_{y}, SiᵤAlᵥOₓN_{y}, diamond, diamond-like carbon, SiₓC_{y}, SiₓO_{y}C_{z}, ZrO₂, TiOₓN_{y}, or combinations thereof.

An aspect (24) of the present disclosure pertains to a foldable apparatus according to any of the aspects (19)-(23), wherein the second layer comprises a residual stress of less than +200 MPa (tensile) to −1100 MPa (compressive).

An aspect (25) of the present disclosure pertains to a foldable apparatus according to the aspect (24), wherein the glass-based layer comprises an asymmetric stress profile configured to counteract warp caused by the residual stress in the second layer.

An aspect (26) of the present disclosure pertains to a foldable apparatus comprising: a cover glass stack comprising a first glass-based layer, the first glass-based layer comprising a first thickness that is greater than or equal to 10 μm and less than or equal to 200 μm; an OLED display panel disposed on the cover glass stack, the OLED display panel comprising a display substrate; and a second glass-based layer disposed on the OLED display panel such that the display substrate is disposed between the first glass-based layer and the second glass-based layer, the second glass-based layer comprising a second thickness that is greater than or equal to 10 μm and less than or equal to 100 μm, wherein: the cover glass stack is protective cover for the OLED display panel so that an image generated by the display is viewable through the cover glass stack, the foldable apparatus is configured to bend at a bend axis, a combined thickness of the first and second glass-based layers is greater than or equal to 30 μm, the second glass-based layer is adhered to the display substrate so that there are no non-adhesive intervening layers between the second glass-based layer and the display substrate, a fold plane containing the bend axis and extending perpendicular to at least a portion of a major surface of the first glass-based layer when the foldable apparatus is in an unbent state extends through glass-based material of the second glass-based layer, and when the foldable apparatus is either (a) held in a state to exhibit a parallel plate distance of 3.0 mm for 120 hours; or (b) held with a waterdrop bend geometry with a minimum separation distance of 1.3 mm for 24 hours and subsequently released, a front surface of the foldable apparatus exhibits a crease height recovery of at least 40% over the 24 hour period after release.

An aspect (27) of the present disclosure pertains to a foldable apparatus according to the aspect (26), wherein at least one of: the second glass-based layer comprises a plurality of segments that are separated from one another by gaps so that the second glass-based layer does not cover an entirety of the display substrate, the second glass-based layer comprises a variable thickness component of glass-based material, the second glass-based layer is a component of a laminate, the laminate comprising an additional layer of glass-based material laminated to the second glass-based layer, and the second glass-based layer comprises a composite article, the composite article comprising: a glass-based layer formed of a glass-based material; and a second layer disposed directly on the glass-based layer, the second layer comprising an elastic modulus that is at least 10 GPa greater than the glass-based layer.

An aspect (28) of the present disclosure pertains to a foldable apparatus according to the aspect (27), wherein the second glass-based layer comprises the variable thickness component and the variable thickness component is the second glass-based layer, which comprises a reduced-thickness portion.

An aspect (29) of the present disclosure pertains to a foldable apparatus according to the aspect (28), wherein the reduced-thickness portion comprises a recessed area of the first major surface of the second glass-based layer facing the OLED display panel.

An aspect (30) of the present disclosure pertains to a foldable apparatus according to the aspect (28), wherein the reduced-thickness portion comprises a recessed area of a second major surface of the second glass-based layer facing away from the OLED display panel.

An aspect (31) of the present disclosure pertains to a foldable apparatus according to any of the aspects (28)-(30), wherein the reduced thickness portion is centered at the bend axis.

An aspect (32) of the present disclosure pertains to a foldable apparatus according to the aspect (27), wherein: the second glass-based layer comprises the plurality of segments, and the plurality of segments comprise a central segment centered on the bend axis and two or more off-center segments offset from the central segment away from the bend axis.

An aspect (33) of the present disclosure pertains to a foldable apparatus according to any of the aspects (26)-(32), wherein the cover glass stack comprises an additional layer of glass-based material attached to the first glass-based layer by a layer of optically clear adhesive.

An aspect (34) of the present disclosure pertains to a foldable apparatus according to any of the aspects (26)-(33), wherein the second glass-based layer comprises a glass ceramic.

An aspect (35) of the present disclosure pertains to a foldable apparatus according to any of the aspects (26)-(34), wherein a Young's modulus of the second glass-based layer is at least 5 GPa greater than a Young's modulus of the first glass-based layer.

An aspect (36) of the present disclosure pertains to a foldable apparatus according to any of the aspects (26)-(35), wherein the second glass-based layer comprises glass-based material with a thermal conductivity greater than or equal to 0.05 W*m⁻¹*K⁻¹.

An aspect (37) of the present disclosure pertains to a foldable apparatus according to any of the aspects (26)-(36), wherein: both the first glass-based layer and glass-based material of the second glass-based layer are ion exchanged so that they have regions of compressive stress extending inward from major surfaces thereof, each of the first glass-based layer and the second glass-based layer consists of a single layer of glass-based material, and at least one of: the first glass-based layer exhibits a greater maximum compressive stress (CS) than that of the second glass-based layer, and the first glass-based layer exhibits a ratio of CS (in MPa) to Young's modulus (in GPa) that is at least 1.0 (units omitted) greater than that of the second glass-based layer.

An aspect (38) of the present disclosure pertains to a foldable apparatus according to the aspect (26), wherein: the second glass-based layer comprises the composite article, and at least one of: the second layer comprises a thickness that is greater than or equal to 1 μm and less than or equal to 10 μm, the thickness of the second layer is at least 2.0% of a thickness of the glass-based layer, an overall thickness of the composite article is less than or equal to 100 μm, the second layer comprises Al₂O₃, AlN, AlOₓN_{y}, Si₃N₄, SiOₓN_{y}, SiᵤAlᵥOₓN_{y}, diamond, diamond-like carbon, SiₓC_{y}, SiₓO_{y}C_{z}, ZrO₂, TiOₓN_{y}, or combinations thereof, the second layer comprises a residual stress of less than +200 MPa (tensile) to −1100 MPa (compressive), and the glass-based layer comprises an asymmetric stress profile configured to counteract warp caused by the residual stress in the second layer.

An aspect (39) of the present disclosure pertains to a foldable apparatus according to any of the aspects (26)-(38), wherein: when the foldable apparatus is maintained in a bent state for a time period of at least 24 hours so that a front surface of foldable apparatus exhibits a minimum bend radius of less than 20 mm and subsequently released, the foldable apparatus comprises a crease region, and the second glass-based layer comprises a continuous volume of glass-based material with a minimum thickness of at least 10 μm within the crease region.

An aspect (40) of the present disclosure pertains to a foldable apparatus according to any of the aspects (26)-(39), wherein the second glass-based layer is adhered to the display substrate so that there are no non-adhesive intervening layers between the second glass-based layer and the display substrate,

An aspect (41) of the present disclosure pertains to a foldable apparatus according to any of preceding aspects, wherein, when the second glass-based layer is a component of the laminate, a glass-based layer of the laminate most proximate to the OLED display panel exhibits at least one of: (a) a greatest thickness of all the glass-based layers in the laminate and; (b) a greatest elastic modulus of all the glass-based layers in the laminate.

An aspect (42) of the present disclosure pertains to a foldable device comprising a housing comprising a first housing member, a second housing member, and a hinge structure connecting the first housing member to the second housing member, a foldable apparatus of any of the aspects (1)-(38) disposed in the housing, wherein: the housing is reversibly reconfigurable between an open configuration and a closed configuration in which the foldable apparatus is bent such that first and second portions of the foldable apparatus overlap one another, and when the housing is in the closed configuration, the foldable apparatus is bent in a waterdrop configuration.

### BRIEF DESCRIPTION OF THE DRAWINGS

The above and other features and advantages of embodiments of the present disclosure are better understood when the following detailed description is read with reference to the accompanying drawings, in which:

FIG. 1 is a schematic view of an example foldable apparatus in an open configuration, according to one or more embodiments of the present disclosure;

FIGS. 2A-2D are cross-sectional views of the foldable apparatus along line 2-2 of FIG. 1, according to embodiments of the present disclosure;

FIG. 3 is a cross-sectional view of a testing apparatus to determine the effective minimum bend radius of foldable apparatus, according to one or more embodiments of the present disclosure;

FIG. 4 schematically depicts an apparatus for determining a pen drop performance of a foldable apparatus, according to one or more embodiments of the present disclosure.

FIG. 5 depicts a modelled counter example foldable apparatus stack, according to one or more embodiments of the present disclosure;

FIGS. 6A-6E depict modelled example foldable apparatus stacks, according to one or more embodiments of the present disclosure;

FIG. 7 is a plot of strains in layers of a display surrogate when the example foldable apparatus stacks are bent with a parallel plate distance of 3 mm, according to one or more embodiments of the present disclosure;

FIG. 8A is a plot of maximum principle stress as a function of load when the modelled examples are subjected to a Quasi Static Puncture test, according to one or more embodiments of the present disclosure;

FIG. 8B is a plot of normal stress as a function of thickness location in each of the modelled examples when the modelled examples are subjected to the Quasi Static Puncture test, according to one or more embodiments of the present disclosure;

FIG. 8C is a plot of shear strain as a function of load when the modelled examples are subjected to a Quasi Static Puncture test, according to one or more embodiments of the present disclosure;

FIGS. 9A-9B depict an apparatus used to model the creasing performance of modelled examples, according to one or more embodiments of the present disclosure;

FIGS. 10A-10B are plots of modelled shapes of front surfaces of the modelled examples directly after release from being held at a parallel plate distance for 120 hours and after a 24 hour wait time, according to one or more embodiments of the present disclosure;

FIG. 11A-11B are perspective and cross-sectional views, respectively, of a foldable device incorporating a foldable apparatus, according to one or more embodiments of the present disclosure;

FIGS. 12A-12B depict modelled example foldable apparatus stacks, according to one or more embodiments of the present disclosure;

FIGS. 13A-13B depict an apparatus used to model the creasing performance of modelled examples, according to one or more embodiments of the present disclosure;

FIGS. 14A-14B are plots of modelled shapes of front surfaces of the modelled examples depicted in FIGS. 12A-12B, 2 minutes after release from being held in a waterdrop configuration for 24 hours and after a 24 hour wait time, according to one or more embodiments of the present disclosure;

FIG. 14C is a plot of strains in layers of the modelled examples depicted in FIGS. 12A-12B when held in the waterdrop configuration, according to one or more embodiments of the present disclosure;

FIG. 15 schematically depicts a composite article that can be used as a second glass-based layer in an underside stack, according to one or more embodiments of the present disclosure;

FIG. 16 schematically depicts a composite article where a glass-based layer therefor is not completely covered by a second layer, according to one or more embodiments of the present disclosure; and

FIG. 17 is a plot of modelled shapes of front surfaces of the Examples 7 and 8, four seconds after release from being held in a waterdrop configuration for 24 hours, according to one or more embodiments of the present disclosure.

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Embodiments will now be described more fully hereinafter with reference to the accompanying drawings in which example embodiments are shown. Whenever possible, the same reference numerals are used throughout the drawings to refer to the same or like parts. However, claims may encompass many different aspects of various embodiments and should not be construed as limited to the embodiments set forth herein.

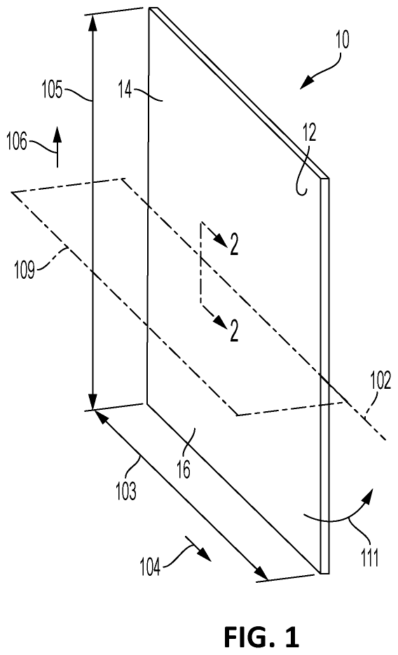

FIGS. 1-3 illustrate views of foldable apparatus 10 in accordance with embodiments of the disclosure. Unless otherwise noted, a discussion of features of embodiments of one foldable apparatus can apply equally to corresponding features of any of the embodiments of the disclosure. For example, identical part numbers throughout the disclosure can indicate that the identified features are identical to one another and that the discussion of the identified feature of one embodiment, unless otherwise noted, can apply equally to the identified feature of any of the other embodiments of the disclosure.

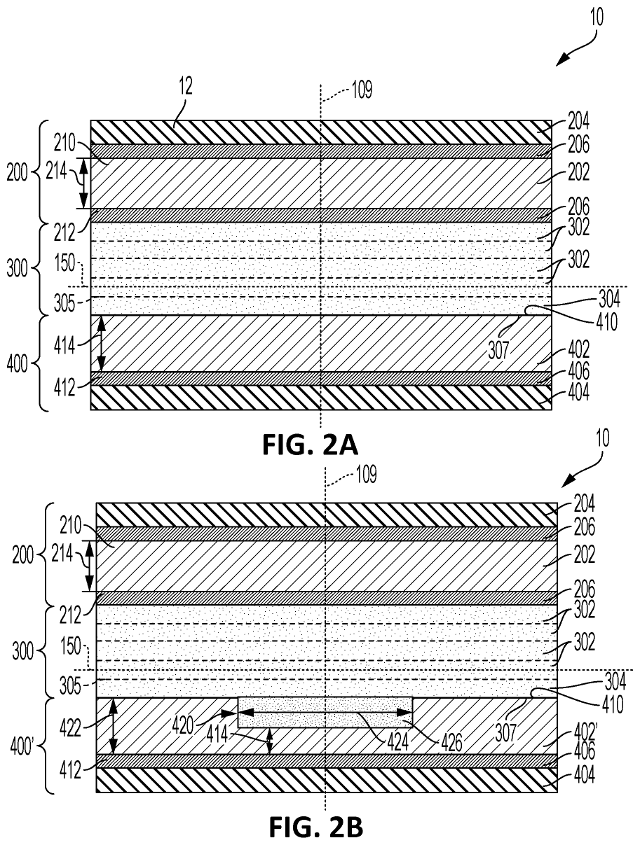

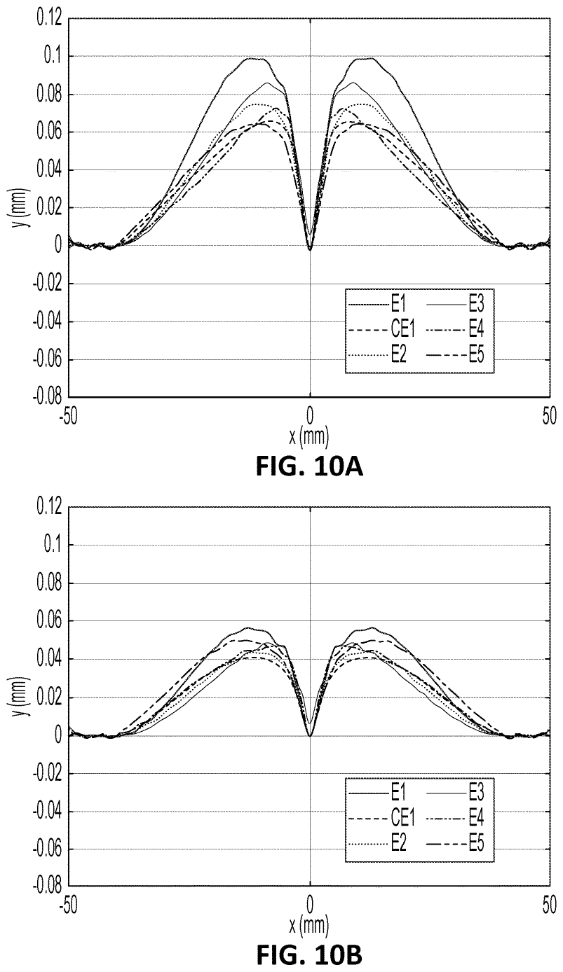

FIG. 1 schematically depicts a foldable apparatus 10, in accordance with embodiments of the present disclosure. The foldable apparatus 10 is configured to be reversibly reconfigurable between an unfolded (or open) state and a folded (or closed) state by bending at a bend axis 102. A fold plane includes the bend axis 102 and extends through the foldable apparatus 10 in a direction perpendicular to a portion of a first major surface 210 of the first glass-based layer 202 (see e.g., FIG. 2A) when the foldable apparatus is unfolded. The foldable apparatus 10 includes a first portion 14 disposed on a first side of the bend axis 102 and a second portion 16 disposed on a second side of the bend axis 102. In aspects, the foldable apparatus 10 can be situated in a bendable (e.g., hinged) housing of an incorporating device (example shown in FIG. 11) that determines the precise location of bend axis 102 and the shape that the foldable apparatus 10 takes in each of the unfolded and folded states. In aspects, the first and second portions 14 and 16 are the portions of the front surface that do not change in shape as a result of the incorporating device being bent between a folded and unfolded configuration (corresponding to the first and second portions 20 and 30 described herein with respect to FIGS. 11A and 11B). The bend axis 102 can be situated such that, when the foldable apparatus 10 is bent to a maximum extent associated with the application (e.g., so that the first and second portions 14 and 16 exhibit a minimum parallel plate distance), the bend axis 102 symmetrically divides a bent portion of the front surface 12 of the foldable apparatus 10.

FIG. 1 depicts the foldable apparatus 10 in an unfolded state. The particular configuration of the foldable apparatus 10 when in the unfolded state can vary depending on the implementation. In the embodiment depicted in FIG. 1, for example, the foldable apparatus 10 (or at least the front surface 12 thereof) can exhibit a planar (or substantially planar) shape, so that any deviations in the front surface 12 from a planar shape are localized around the bend axis 102. In such embodiments, portions of the front surface 12 at least 50 mm away from the bend axis 102 along a direction 106 perpendicular thereto can exhibit low distortion (<1 D, or even <0.5 D) Sk (in diopters) measured by a phase deflectometry system (available from ISRA VISION GmbH, Dramstadt, Germany, under the trade name ISRA SpecGage3D), with 0.3 mm pixel size. When the foldable apparatus 10 comprises a substantially planar shape in the unfolded state, a straight line can be drawn across the foldable apparatus 10 in the direction 106 that touches at least some of the first and second portions 14 and 16.

Throughout the disclosure, with reference to FIG. 1, the width 103 of the foldable apparatus 10 is considered the dimension of the foldable apparatus 10 taken between opposed edges of the foldable apparatus in a direction 104 of the bend axis 102. Furthermore, throughout the disclosure, a length 105 of the foldable apparatus 10 is considered the dimension of the foldable apparatus 10 taken between opposed edges in a direction 106 perpendicular to the bend axis 102. As shown, the foldable apparatus 10 may include a single bend axis to allow the foldable apparatus to comprise a bifold wherein, for example, the foldable apparatus may be folded in half. In further embodiments, the foldable apparatus may include two or more fold axes. For example, providing two fold axes can allow the foldable apparatus 10 to comprise a trifold wherein, for example, the foldable apparatus 10 may be folded with three portions.

FIG. 2A schematically depicts a cross-sectional view of the foldable apparatus 10 through the line 2-2, according to an example embodiment. Unless otherwise noted herein, components depicted in cross-sectional views in the lengthwise direction, such as that depicted in FIG. 2A, extend an entirety of the width 103 of the foldable apparatus 10. As shown, the foldable apparatus 10 includes a cover glass stack 200, an organic light emitting diode (“OLED”) display panel 300, and an underside stack 400. The OLED display panel 300 can be implemented as a touch-panel display and comprise a touch panel and componentry configured to generate images that are viewable by a user through the cover glass stack 200. The OLED display panel 300 comprises a plurality of device layers 302 disposed on a display substrate 304. The plurality of device layers 302 can comprise any configuration of layers (e.g., anode, emissive layers, electron touch panel, cathode, and others) known in the art to utilize OLED technology to generate a pixelated display image. The display substrate 304 supports the plurality of device layers 302 and can be formed of any suitable material (e.g., plastic or glass). For example, an anode can be a conductive layer disposed and formed on the display substrate 304.

### Cover Glass Stack

The cover glass stack 200 is configured to protect the OLED display panel 300 from the external environment of the foldable apparatus 10 to ensure operability of the OLED display panel 300. To provide visibility of images generated by the OLED display panel 300 through the cover glass stack 200, the cover glass stack 200 (and any of the individual component layers contained therein) can be optically transparent. As used herein, “optically transparent” or “optically clear” means an average transmittance of 70% or more in the wavelength range of 400 nm to 700 nm through the referenced stack or layer of material. In aspects, the cover glass stack 200, or any of its individual component layers, may have an average transmittance of 75% or more, 80% or more, 85% or more, or 90% or more, 92% or more, 94% or more, 96% or more in the wavelength range from 400 nm to 700 nm through the entire thickness thereof. The average transmittance in the wavelength range of 400 nm to 700 nm is calculated by averaging transmittance measurements at whole number wavelengths from about 400 nm to about 700 nm.

The cover glass stack 200 comprises a first glass-based layer 202 and (optionally) a polymer-based layer 204 that are attached to one another and to the OLED display panel 300 via layers of optically clear adhesive 206. The polymer-based layer 204 can be included to protect the first glass-based layer 202 and to retain fragments of the first glass-based layer 202 in the event of fracture. In aspects, the foldable apparatus 10 can include more than one polymer-based layer 204 (e.g., an additional polymer-based layer over what is shown can be included on top of the polymer-based layer 204). The polymer-based layer 204 can comprise a rigid polymer (e.g., comprising an elastic modulus at 25 °C of about 3 GigaPascals (GPa) or more, about 8 GPa or more, about 9 GPa or more, or about 10 GPa or more). Example embodiments of rigid polymers include but are not limited to blends, nanoparticle, and/or fiber composites of one or more of styrene-based polymers (e.g., polystyrene (PS), styrene acrylonitrile (SAN), styrene maleic anhydride (SMA)), phenylene-based polymers (e.g., polyphenylene sulfide (PPS)), polyvinylchloride (PVC), polysulfone (PSU), polyphthalmide (PPA), polyoxymethylene (POM), polylactide (PLA), polyimides (PI), polyhydroxybutyrate (PHB), polyglycolides (PGA), polyethyleneterephthalate (PET), and/or polycarbonate (PC). In aspects, the polymer-based layer 204 can have an elastic modulus in a range from about 1 GPa to about 18 GPa, from about 3 GPa to about 18 GPa, from about 3 GPa to about 10 GPa, from about 5 GPa to about 10 GPa, from about 3 GPa to about 5 GPa, from about 1 GPa to about 10 GPa, from about 1 GPa to about 5 GPa, from about 1 GPa to about 3 GPa, or any range or subrange therebetween. Throughout the disclosure, a tensile strength, ultimate elongation (e.g., strain at failure), and yield point of a polymeric material (e.g., adhesive, polymer-based portion) is determined using ASTM D638 using a tensile testing machine, for example, an Instron 3400 or Instron 6800, at 25 °C and 50% relative humidity with a type I dogbone shaped sample. Throughout the disclosure, an elastic modulus (e.g., Young's modulus) and/or a Poisson's ratio is measured using ISO 527-1:2019.

The first glass-based layer 202 is incorporated to provide suitable hardness, impact resistance, and scratch resistance to the cover glass stack 200. In this regard, the first glass-based layer 202 can be formed of a glass-based material. As used herein, “glass-based” includes both glasses and glass-ceramics, wherein glass-ceramics have one or more crystalline phases and an amorphous, residual glass phase. Glass-based material can cool or has already cooled into a glass, glass-ceramic, and/or that upon further processing becomes a glass-ceramic material. A glass-based material (e.g., glass-based substrate) may comprise an amorphous material (e.g., glass) and optionally one or more crystalline materials (e.g., ceramic). Amorphous materials and glass-based materials may be strengthened. As used herein, the term “strengthened” may refer to a material that has been chemically strengthened, for example, through ion-exchange of larger ions for smaller ions in the surface of the substrate, as discussed below. However, other strengthening methods, for example, thermal tempering, or utilizing a mismatch of the coefficient of thermal expansion between portions of the substrate to create compressive stress and central tension regions, may be utilized to form strengthened substrates. Exemplary glass-based materials, which may be free of lithia or not, comprise soda lime glass, alkali aluminosilicate glass, alkali-containing borosilicate glass, alkali-containing aluminoborosilicate glass, alkali-containing phosphosilicate glass, and alkali-containing aluminophosphosilicate glass. In one or more embodiments, a glass-based material may comprise, in mole percent (mol %): SiO₂ in a range from about 40 mol % to about 80%, Al₂O₃ in a range from about 10 mol % to about 30 mol %, B₂O₃ in a range from 0 mol % to about 10 mol %, ZrO₂ in a range from 0 mol % to about 5 mol %, P₂O₅ in a range from 0 mol % to about 15 mol %, TiO₂ in a range from 0 mol % to about 2 mol %, R₂O in a range from 0 mol % to about 20 mol %, and RO in a range from 0 mol % to about 15 mol %. As used herein, R₂O can refer to an alkali metal oxide, for example, Li₂O, Na₂O, K₂O, Rb₂O, Cs₂O, or combinations thereof. As used herein, RO can refer to MgO, CaO, SrO, BaO, ZnO, or combinations thereof. In some embodiments, a glass-based substrate may optionally further comprise in a range from 0 mol % to about 2 mol % of each of Na₂SO₄, NaCl, NaF, NaBr, K₂SO₄, KCl, KF, KBr, As₂O₃, Sb₂O₃, SnO₂, Fe₂O₃, MnO, MnO₂, MnO₃, Mn₂O₃, Mn₃O₄, and/or Mn₂O₇. “Glass-ceramics” include materials produced through controlled crystallization of glass. In some embodiments, glass-ceramics can comprise about 1% to about 99% crystallinity. Examples of suitable glass-ceramics may include Li₂O—Al₂O₃—SiO₂ system (i.e., LAS-System) glass-ceramics, MgO—Al₂O₃—SiO₂ system (i.e., MAS-System) glass-ceramics, ZnO×Al₂O₃×nSiO₂ (i.e., ZAS system), and/or glass-ceramics that include a predominant crystal phase including β-quartz solid solution, β-spodumene, cordierite, petalite, and/or lithium disilicate. Glass-ceramic substrates may be strengthened using strengthening processes described herein. In one or more embodiments, MAS-System glass-ceramic substrates may be strengthened in Li₂SO₄ molten salt, whereby an exchange of 2Li⁺ for Mg²⁺ can occur.

In aspects, the first glass-based layer 202 can comprise a glass-based portion and/or a ceramic-based portion having a pencil hardness of 8H or more, for example, 9H or more. As used herein, pencil hardness is measured using ASTM D 3363-20 with standard lead graded pencils. In some embodiments, the first glass-based layer 202 can comprise a ceramic-based portion, which may or may not be strengthened. As used herein, “ceramic-based” includes both ceramics and glass-ceramics, wherein glass-ceramics have one or more crystalline phases and an amorphous, residual glass phase. In some embodiments, a ceramic-based material can be formed by heating a glass-based material to form ceramic (e.g., crystalline) portions. In further embodiments, ceramic-based materials may comprise one or more nucleating agents that can facilitate the formation of crystalline phase(s). In some embodiments, the ceramic-based materials can comprise one or more oxides, nitrides, oxynitrides, carbides, borides, and/or silicides. Example embodiments of ceramic oxides include zirconia (ZrO₂), zircon (ZrSiO₄), an alkali metal oxide (e.g., sodium oxide (Na₂O)), an alkali earth metal oxide (e.g., magnesium oxide (MgO)), titania (TiO₂), hafnium oxide (Hf₂O), yttrium oxide (Y₂O₃), iron oxides, beryllium oxides, vanadium oxide (VO₂), fused quartz, mullite (a mineral comprising a combination of aluminum oxide and silicon dioxide), and spinel (MgAl₂O₄). Example embodiments of ceramic nitrides include silicon nitride (Si₃N₄), aluminum nitride (AlN), gallium nitride (GaN), beryllium nitride (Be₃N₂), boron nitride (BN), tungsten nitride (WN), vanadium nitride, alkali earth metal nitrides (e.g., magnesium nitride (Mg₃N₂)), nickel nitride, and tantalum nitride. Example embodiments of oxynitride ceramics include silicon oxynitride, aluminum oxynitride, and a SiAlON (a combination of alumina and silicon nitride and can have a chemical formula, for example, Si₁₂₋ₘ₋ₙAlₘ₊ₙOₙN₁₆₋ₙ, Si₆₋ₙAlₙOₙN₈₋ₙ, or Si₂₋ₙAlₙO₁₊ₙN₂₋ₙ, where m, n, and the resulting subscripts are all non-negative integers). Example embodiments of carbides and carbon-containing ceramics include silicon carbide (SiC), tungsten carbide (WC), an iron carbide, boron carbide (B₄C), alkali metal carbides (e.g., lithium carbide (Li₄C₃)), alkali earth metal carbides (e.g., magnesium carbide (Mg₂C₃)), and graphite. Example embodiments of borides include chromium boride (CrB₂), molybdenum boride (Mo₂B₅), tungsten boride (W₂B₅), iron boride, titanium boride, zirconium boride (ZrB₂), hafnium boride (HfB₂), vanadium boride (VB₂), Niobium boride (NbB₂), and lanthanum boride (LaB₆). Example embodiments of silicides include molybdenum disilicide (MoSi₂), tungsten disilicide (WSi₂), titanium disilicide (TiSi₂), nickel silicide (NiSi), alkali earth silicide (e.g., sodium silicide (NaSi)), alkali metal silicide (e.g., magnesium silicide (Mg₂Si)), hafnium disilicide (HfSi₂), and platinum silicide (PtSi).

In aspects, the first glass-based layer 202 can comprise an elastic modulus in a range from about 1 GPa to about 120 GPa, from about 40 GPa to about 100 GPa, from about 60 GPa to about 100 GPa, from about 60 GPa to about 80 GPa, from about 80 GPa to about 100 GPa, or any range or subrange therebetween. Maintaining the elastic modulus of the beneath 75 GPa (e.g., from 50 GPa to 70 GPa, from 50 GPa to less than 75 GPa) can beneficial reduce bending-induced stresses placed on the first glass-based layer 202 when the foldable apparatus 10 is placed into the folded state described herein.

As shown in FIG. 2A, the first glass-based layer 202 comprises a first major surface 210 and a second major surface 212 opposite the first major surface 210. The first glass-based layer 202 has a first thickness 214 defined as a minimum distance between the first major surface 210 and the second major surface 212. In some embodiments, the thickness of the first glass-based layer 202 can be substantially uniform across the first major surface 210. In some embodiments, the first thickness 214 can be about 10 micrometers (μm) or more, about 25 μm or more, about 30 μm or more, about 50 μm or more, 80 μm or more, about 100 μm or more, about 125 μm or more, about 500 μm or less, about 500 μm or less, about 125 μm or less, about 100 μm or less, about 75 μm or less, or about 50 μm or less. In some embodiments, the first thickness 214 can be from about 10 μm to about 500 μm, from about 10 μm to about 100 μm, from about 10 μm to about 70 μm, from about 10 μm to about 50 μm, from about 20 μm to about 50 μm, from about 30 μm to about 50 μm, or any range or subrange therebetween. In aspects, lower thicknesses in the preceding ranges (e.g., thicknesses less than or equal to 75 μm) can beneficially reduce the flexural rigidity of the cover glass stack 200 and limit bending-induced stresses placed on the first glass-based layer 202 from folding the foldable apparatus 10. In aspects, the cover glass stack 200 can include multiple first glass-based layers (e.g., two glass-based layers laminated to one another via a layer of optically clear adessive), with each of the glass-based layers having a thickness and other properties in any of the ranges provided herein with respect to the first glass-based layer 202.

In aspects, the first glass-based layer 202 may comprise a compressive stress region. In some embodiments, the compressive stress region may be created by chemically strengthening. Chemically strengthening may comprise an ion exchange process, where ions in a surface layer are replaced by—or exchanged with—larger ions having the same valence or oxidation state. Methods of chemically strengthening will be discussed later. Without wishing to be bound by theory, chemically strengthening the first glass-based layer 202 can enable good impact resistance and/or good puncture resistance (e.g., resists failure for a pen drop height of 10 centimeters (cm) or more, 15 cm or more, or 20 cm or more). Without wishing to be bound by theory, chemically strengthening the first glass-based layer 202 can enable small bend radii because the compressive stress from the chemical strengthening can counteract the bend-induced tensile stress on the outermost surface of the substrate. A compressive stress region may extend into the first glass-based layer 202 for a depth called the depth of compression. As used herein, depth of compression means the depth at which the stress in the chemically strengthened substrates and/or portions described herein changes from compressive stress to tensile stress. Depth of compression may be measured by a surface stress meter or a scattered light polariscope (SCALP, wherein values reported herein were made using SCALP-5 made by Glasstress Co., Estonia) depending on the ion exchange treatment and the thickness of the article being measured. Where the stress in the substrate and/or portion is generated by exchanging potassium ions into the substrate, a surface stress meter, for example, the FSM-6000 (Orihara Industrial Co., Ltd. (Japan)), is used to measure depth of compression. Unless specified otherwise, compressive stress (including surface CS) is measured by surface stress meter (FSM) using commercially available instruments, for example the FSM-6000, manufactured by Orihara. Surface stress measurements rely upon the accurate measurement of the stress optical coefficient (SOC), which is related to the birefringence of the glass. Unless specified otherwise, SOC is measured according to Procedure C (Glass Disc Method) described in ASTM standard C770-16, entitled “Standard Test Method for Measurement of Glass Stress-Optical Coefficient,” the contents of which are incorporated herein by reference in their entirety. Where the stress is generated by exchanging sodium ions into the substrate, and the article being measured is thicker than about 400 μm, SCALP is used to measure the depth of compression and central tension (CT). Where the stress in the substrate and/or portion is generated by exchanging both potassium and sodium ions into the substrate and/or portion, and the article being measured is thicker than about 400 μm, the depth of compression and CT are measured by SCALP. Without wishing to be bound by theory, the exchange depth of sodium may indicate the depth of compression while the exchange depth of potassium ions may indicate a change in the magnitude of the compressive stress (but not the change in stress from compressive to tensile). The refracted near-field (RNF; the RNF method is described in U.S. Pat. No. 8,854,623, entitled “Systems and methods for measuring a profile characteristic of a glass sample”, which is incorporated herein by reference in its entirety) method also may be used to derive a graphical representation of the stress profile. When the RNF method is utilized to derive a graphical representation of the stress profile, the maximum central tension value provided by SCALP is utilized in the RNF method. The graphical representation of the stress profile derived by RNF is force balanced and calibrated to the maximum central tension value provided by a SCALP measurement. As used herein, “depth of layer” means the depth that the ions have exchanged into the substrate and/or portion (e.g., sodium, potassium). Through the disclosure, when the maximum central tension cannot be measured directly by SCALP (as when the article being measured is thinner than about 400 μm) the maximum central tension can be approximated by a product of a maximum compressive stress and a depth of compression divided by the difference between the thickness of the substrate and twice the depth of compression, wherein the compressive stress and depth of compression are measured by FSM.

In some embodiments, the first glass-based layer 202 may comprise a first compressive stress region at the first major surface 210 that can extend to a first depth of compression from the first major surface 210 and a second compressive stress region at the second major surface 2012 that can extend to a second depth of compression from the second major surface 212.

In some embodiments, the first depth of compression and/or the second depth of compression as a percentage of the first thickness 214 can be about 1% or more, about 5% or more, about 10% or more, about 30% or less, about 25% or less, or about 20% or less. In some embodiments, the first depth of compression and/or the second depth of compression as a percentage of the first thickness 214 can be in a range from about 1% to about 30%, from about 5% to about 30%, from about 10% to about 30%, from about 10% to about 25%, from about 15% to about 25%, from about 15% to about 20%, or any range or subrange therebetween. In further embodiments, the first depth of compression can be substantially equal to the second depth of compression. In some embodiments, the first depth of compression and/or the second depth of compression can be about 1 μm or more, or about 10 μm or more, or about 50 μm or less. In some embodiments, the first depth of compression and/or the second depth of compression can be in a range from about 1 μm to about 50 μm, from about 1 μm to about 25 μm, from about 1 μm to about 10 μm, from about 1 μm to about 5 μm, or any range or subrange therebetween. By providing a first glass-based layer 202 comprising a first depth of compression and/or a second depth of compression in a range from about 1% to about 30% of the substrate thickness, good impact resistance, good puncture resistance, and/or good folding performance can be enabled.

In aspects, the first compressive stress region can comprise a first maximum compressive stress. In some embodiments, the second compressive stress region can comprise a second maximum compressive stress. In further embodiments, the first maximum compressive stress and/or the second maximum compressive stress can be about 100 MegaPascals (MPa) or more, about 300 MPa or more, about 500 MPa or more, about 600 MPa or more, about 700 MPa or more, about 1,500 MPa or less, about 1,200 MPa or less, or about 1,000 MPa or less. In further embodiments, the first maximum compressive stress and/or the second maximum compressive stress can be in a range from about 100 MPa to about 1,500 MPa, from about 300 MPa to about 1,500 MPa, from about 500 MPa to about 1,500 MPa, from about 500 MPa to about 1,200 MPa, from about 500 MPa to about 1,000 MPa, from about 600 MPa to about 1,000 MPa, or from about 700 MPa to about 1,000 MPa, or any range or subrange therebetween. In some embodiments, the first maximum compressive stress and/or the second maximum compressive stress can be in a range from about 500 MPa to about 1,500 MPa, from about 600 MPa to about 1,500 MPa, from about 600 MPa to about 1,200 MPa, from about 700 MPa to about 1,200 MPa, from about 700 MPa to about 1,000 MPa, or any range or subrange therebetween. By providing a first maximum compressive stress and/or a second maximum compressive stress in a range from about 500 MPa to about 1,500 MPa, good impact resistance, good puncture resistance, and/or good folding performance can be enabled.

Referring still to FIG. 2A, the layers of optically clear adhesive 206 can comprise a thickness from 1 μm to 100 μm and be formed of a material having a suitable optical transparency and rigidity. For example, the layers of optically clear adhesive 206 can be formed of an optically clear adhesive can comprise one or more of the following polymethylmethacrylate (PMMA)), an epoxy, silicone and/or a polyurethane. Examples of epoxies include bisphenol-based epoxy resins, novolac-based epoxies, cycloaliphatic-based epoxies, and glycidylamine-based epoxies. In even further embodiments, the optically clear adhesive can comprise, but is not limited to, acrylic adhesives, for example, 3M 8212 adhesive, or an optically transparent liquid adhesive, for example, a LOCTITE optically transparent liquid adhesive. Exemplary embodiments of optically clear adhesives comprise transparent acrylics, epoxies, silicones, and polyurethanes. For example, the optically transparent liquid adhesive could comprise one or more of LOCTITE AD 8650, LOCTITE AA 3922, LOCTITE EA E-05MR, LOCTITE UK U-09LV, which are all available from Henkel.

In aspects, the material forming the layers of optically clear adhesive 206 can comprise an elastic modulus of about 0.01 MegaPascals (MPa) or more, about 1 MPa or more, about 10 MPa or more, about 20 MPa or more, about 100 MPa or more, about 10,000 MPa or less, about 3,000 MPa or less, about 1,000 MPa or less, about 500 MPa or less, or about 300 MPa or less. In some embodiments, the first adhesive 211 and/or the second adhesive 221 can comprise an elastic modulus in a range from about 0.01 MPa to about 10,000 MPa, from about 0.01 MPa to about 3,000 MPa, from about 1 MPa to about 3,000 MPa, from about 10 MPa to about 3,000 MPa, from about 20 MPa to about 3,000 MPa, from about 20 MPa to about 1,000 MPa, from about 20 MPa to about 300 MPa, from about 100 MPa to about 300 MPa, from about 200 MPa to about 300 MPa, or any range or subrange therebetween.

### Underside Stack

Referring still to FIG. 2A, the underside stack 400 is situated such that the display substrate 304 is disposed between the underside stack 400 and the cover glass stack 200. In accordance with the present disclosure, the underside stack 400 comprises a second glass-based layer 402. Certain existing foldable apparatuses include an underside stack without any glass-based materials therein. For example, certain existing devices may include a metallic (e.g., alloy) backing layer to facilitate appropriate placing of a neutral axis in the display panel to avoid display component failure from the persistent bending-induced stresses that the display panel is exposed to. Such metallic materials are believed to suffer from issues such as creep that can lead to creasing or other localized bending in the apparatus that can cause performance issues. It is believed that the glass-based materials out of which the second glass-based layer 402 can have sufficient elastic modulus to facilitate placement of a neutral plane 150 proximate to the display substrate 304 when the foldable apparatus 10 is bent. Such placement of the neutral plane 150 can aid in lowering tensile strains that certain layers of the OLED display panel 300 are exposed to during bending, as compared to existing foldable apparatuses without a glass-based material in the underside stack. Moreover, glass-based materials do not suffer from issues such as creep to an extent as great as certain metallic-based materials that are currently used, thereby alleviating some of the aforementioned issues with materials that are currently used in underside stacks. Glass-based materials are also thought to have superior strain recovery characteristics than other (e.g., metal and plastic) materials, and so replacing such other materials with a glass-based material is believed to potentially improve creasing recovery performance of the foldable apparatus 10 over existing apparatuses employing such other materials.

As shown in FIG. 2A, the second glass-based layer 402 includes a first major surface 410 and a second major surface 412. The second glass-based layer 402 also includes a second thickness 414 extending between the first and second major surfaces 410 and 412 (representing a minimum distance between the respective major surfaces). In aspects, the second glass-based layer 402, as well as the second thickness 414, can be formed of any of the glass-based materials, and can have parameters (e.g., thickness, compressive stress regions, modulus) lying in any of the ranges described herein with respect to the glass-based material of the first glass-based layer 202. Glass-based materials that can be used for the second glass-based layer 402 can have a number of beneficial properties to facilitate operation of the foldable apparatus 10.

In aspects, the second glass-based layer 402 can be optically transparent. This can be beneficial in that it can facilitate the OLED display panel 300 being implemented as a double-sided display (e.g., to emit images from both sides thereof) or a transparent display. A double sided display can facilitate the OLED display panel 300 transmitting images from different sides thereof depending on whether the foldable apparatus 10 is in a folded or unfolded state. For example, when the foldable apparatus 10 is in a folded state so that first glass-based layer 202 is bent to a greater degree than the second glass-based layer 402, the foldable apparatus 10 may emit a display image through at least a portion of the underside stack 400 that is visible to a user even when the foldable apparatus 10 is folded. The transparency of the second glass-based layer 402 can facilitate using a single structure to transmit images in both directions, thereby providing flexibility in designing the device incorporating the foldable apparatus 10. Embodiments where the second glass-based layer 402 is not optically transparent (e.g., having an average transmittance from 400 nm to 700 nm of less than or equal to 50%, less than or equal to 30%, or even less than or equal to 10%) are also envisioned.

In some aspects, the glass-based material used to form the second glass-based layer 402 can have a low coefficient of thermal expansion. For example in aspects, the second glass-based layer 402 can exhibit a coefficient of thermal expansion (LTCTE), which is obtained by measuring expansion of the glass between the temperatures of 0 °C and 300 °C. In embodiments, the LTCTE is 7.0 ppm/°C or less, 5.6 ppm/°C or less, in particular, 5.3 ppm/°C or less, or even 5.1 ppm/°C or less. Although embodiments with higher LTCTE are envisioned, a lower LTCTE can aid in the thermal resistance of the second glass-based layer 402. As the underside stack 400 may include a thermally conductive layer (e.g., exhibiting a thermal conductivity greater than or equal to 0.05 W*m⁻¹*K⁻¹) for serving as a heat sink for heat generated by the OLED display panel 300, it is believed that such thermal resistance can enhance the durability of the foldable apparatus 10. Alternatively or additionally, the composition of the second glass-based layer 402 may have such a high thermal conductivity (e.g., conductive particles can be added to the second glass-based layer 402) so as to serve as a heat sink for the OLED display panel 300 thereby eliminating the need for materials less well suited for repeated bending.

In aspects, there may be a coefficient of thermal expansion (CTE) differential between the first and second glass-based layers 202 and 402 to facilitate elevating compressive stress levels in one of the layers to potentially improve damage resistance or scratch resistance of the layer with elevated compressive stress. It is believed that such a CTE differential can induce compressive stress in the lower CTE layer during the process of laminating the glass-based layers to the OLED display panel 300. In aspects, a difference in LTCTE between the first and second glass-based layers 202 and 402 can be greater than or equal to 0.4 ppm/°C, greater than or equal to 0.5 ppm, or even greater than or equal to 1.0 ppm/°C, while being less than or equal to 10 ppm/°C.

In aspects, the foldable apparatus 10 is designed such that, in the folded state, the first glass-based layer 202 is bent to a greater degree (to exhibit a smaller minimum radius of curvature) than the second glass-based layer 402. As a result, the second glass-based layer 402 can be subjected to less bending-induced stresses than the first glass-based layer 202. This lower potential exposure to bending-induced stresses provides flexibility in terms of the construction of the second glass-based layer 402. For example, the elastic modulus of the second glass-based layer 402 can be 50 GPa, 55 GPa, 60 GPa, 65 GPa, 70 GPa, 75 GPa, 80 GPa, 85 GPa, 90 GPa, 95 GPa, 100 GPa, 105 GPa, 110 GPa, 115 GPa, 120 GPa, 125 GPa, 130 GPa, 135 GPa, 140 GPa, 145 GPa, 150 GPa, or any modulus lying in any range bounded by any two of the preceding values as inclusive endpoints.

In aspects, the second glass-based layer 402 can be formed from a glass-based material that exhibits an elastic modulus that is greater than that exhibited by the first glass-based layer 202 while subjecting the layer to similar amounts of bending-induced stresses. For example, the elastic modulus of the second glass-based layer 402 can be at least 5 GPa, at least 6 GPa, at least 7 GPa, at least 8 GPa, at least 9 GPa, or at least 10 GPa, or even at least 50 GPa greater than that of the first glass-based layer 202 (all while being less than or equal to 100 GPa greater than). Such greater modulus in the second glass-based layer 402 can aid in providing beneficial placement of the neutral plane 150 (e.g., within the display substrate 304 or within 100 μm of a front surface 305 of the display substrate 304). Such higher modulus can also aid in the foldable apparatus exhibiting a higher crease recovery rate. Alternatively or additionally, the second glass-based layer 402 can exhibit a higher thickness than the first glass-based layer 202 to provide increased rigidity to provide these effects. For example, in aspects, the second thickness 414 can be 5 μm, 10 μm, 15 μm, 20 μm, or even 30 μm greater than the thickness 214, or there may be any thickness difference lying in a ranged bounded by any two of such values as inclusive endpoints (all with the second glass-based layer 402 being less than 100 μm thicker than the first glass-based layer 202). When the second thickness 414 is greater than the first thickness 214, the second glass-based layer 402 can be constructed of a material with a lower elastic modulus than the first glass-based layer 402 (such a construction may allow improved crease recovery performance over implementations without an underside glass layer, while not increasing a bending force necessary to fold and unfold the foldable apparatus 10 to as great of an extent as when the second glass-based layer 402 is formed of a relatively high modulus material). When the second glass-based layer 402 is formed of a material with a greater elastic modulus than the first glass-based layer 202, the second thickness 414 can also be less than the first thickness 214.

In aspects, the second glass-based layer 402 can be formed of a glass-ceramic while the first glass-based layer 202 can be formed of an amorphous glass material. Glass ceramics can be more rigid while providing greater damage resistance than amorphous glass-based materials. Glass ceramics can also be tuned to provide a variety of other features (e.g., transmittances over various wavelength ranges) for providing other functionalities to the foldable apparatus 10.

In aspects, the second glass-based layer 402 is formed of a glass-based material having a different glass composition than the first glass-based layer 202, though embodiments where these layers have the same composition are also contemplated. For example, the smaller amount of bending-induced stresses that the second glass-based layer 402 is exposed can mean that compressive stresses present in the second glass-based layer from chemical strengthening can be less in magnitude than those in the first glass-based layer 202. These less stringent chemical strengthening requirements provide a greater degree of flexibility in composition of the second glass-based layer 402. For example, in aspects, the first glass-based layer 202 is formed of one of the glass compositions described in U.S. Pat. No. 11,820,703 B2, field on Oct. 10, 2022, entitled “Low-Modulus Ion-Exchangeable Glasses with Enhanced Thermal Properties for Manufacturing” or U.S. patent application Ser. No. 19/058,379, entitled “Ion-Exchangeable Glass-Based Articles and Methods of Making the Same” hereby incorporated by reference in their entireties. The second glass-based layer 402 can be formed of a glass-based material exhibiting a lower ratio of maximum compressive stress (in MPa) to elastic modulus (in GPa) (CS/E) than that exhibited by the first glass-based layer 202. In aspects, the first glass-based layer 202 exhibits a CS/E that is greater than or equal to 15, greater than or equal to 16, or even greater than or equal to 17, while the second glass-based layer can exhibit a CS/E that is less than 15, less than or equal to 14, or even less than or equal to 13. As a result, a difference between CS/E values exhibited by the first and second glass-based layers 202 and 402 can be greater than 1, greater than or equal to 2, or even greater than or equal to 3. The reduced CS/E of the second glass-based layer 402 provides flexibility in the composition that can be used for the second glass-based layer 402 (including lower alumina and alkali contents) which provide a number of other beneficial properties (e.g., in terms of damage resistance or rigidity to be provided). In some aspects, at geometric centers thereof, the first glass-based layer 202 can have an Al₂O₃ content that is more than 3 mol % greater than the second glass-based layer 402 and an R₂O content, where R₂O is a combined amount of Na₂O, K₂O, and Li₂O, that is more than 3% greater than exhibited in the second glass-based layer 402. Such compositional flexibility in the second glass-based layer allows the layer to be tailored to provide various functionalities (e.g., UV absorption).

In aspects, the second glass-based layer 402 can be positioned such that the first major surface 410 is positioned within 400 μm of a rear surface 307 of the display substrate 304 (measured in a direction perpendicular to the rear surface 307 when the foldable apparatus 10 is in an un-bent state). For example, in aspects, the first major surface 410 is positioned a vertical distance from the rear surface 307 that is from 1 μm to 400 μm, from 50 μm to 100 μm, from 50 μm to 150 μm, from 100 μm to 250 μm, from 150 μm to 350 μm, or any subrange therebetween. The vertical distance can be a function of other layers that lie between the second glass-based layer 402 and the display substrate 304. For example, in some aspects, only a layer of optically clear adhesive (not depicted), or other adhesive, lies between the second glass-based layer 402 and the display substrate 304. In other aspects, additional layers, such as a heat sink layer and associated adhesive, can lie between the second glass-based layer 402 and the display substrate 304. In aspects, including adhesive layers, as many as 5 layers may lie between the second glass-based layer 402 and the display substrate 304. This placement of the second glass-based layer 402 is believed to facilitate lowering bending-induced strains in the OLED display panel 300. In aspects, there are no (not glass-based) metallic layers disposed between the second glass-based layer 402 and the display substrate 304, signifying the second glass-based layer 402 being used for a rigid support layer in place of any metallic layers.

A number of possible configurations for the second glass-based layer 402 are contemplated and within the scope of the present disclosure. For example, embodiments are envisioned where the second glass-based layer 402 is implemented as a laminate (e.g., multiple glass-based layers adhered to one another via one or more optically clear adhesives).

FIG. 2A depicts an implementation where the second glass-based layer 402 is a monolithic layer of a glass-based material having a uniform thickness. In FIG. 2A, the second glass-based layer 402 is closest layer of non-adhesive material to the display substrate 304 in the underside stack 400. As shown in FIG. 2A, the underside stack 400 includes an adhesive layer 406 and an additional layer 404. A further additional adhesive layer (not depicted) can also be used to adhere the second glass-based layer 402 to the display substrate 304. The adhesive layer 406 can be formed of any of the materials described herein with respect to the layer of optically clear adhesive 206 of the cover glass stack 200, or be formed of any other suitable material. The additional layer 404 is an optional layer that may be present add functionality to the second glass-based layer 402. For example, the additional layer 404 can be a thermally conductive layer to serve as a heat sink. While FIG. 2A depicts the second glass-based layer 402 as being disposed more proximate to the display substrate 304 than the additional layer 404, it should be appreciated that the other configuration (where the second glass-based layer 402 is the rearmost layer in the underside stack 400 that is directly attached to the OLED display panel 300) is also contemplated and within the scope of the present disclosure.

As described in greater detail herein, when the foldable apparatus 10 is maintained in a bent state (e.g., in the closed configuration described in greater detail herein, at a bend radius that is within 5 mm of an effective minimum bend radius) for a substantial time period (e.g., 24 hours) and subsequently retained to the flat configuration depicted in FIG. 1, the foldable apparatus 10 may tend to exhibit some degree of creasing proximate to the bend axis 102. When the foldable apparatus 10 exhibits creasing, the front surface 102 can substantially deviate from a flat, planar shape. If left in an unbent state, the materials in the foldable apparatus 10 can recover and the creasing may become less pronounced with time. When the foldable apparatus 10 is held in the bent state for the substantial time period and released, the front surface 12 may tend to exhibit a trough at the bend axis 102 (where the surface height of the front surface exhibits a local minimum value hₘᵢₙ). The trough has a height (tₕ) that is a difference between the local minimum surface height (hₘᵢₙ) and a maximum value of the surface height of the front surface. As used herein, the “crease region” is measured at a geometric center of the foldable apparatus (or at a center of a region of overlap between a bend axis and the foldable apparatus, if the bend axis is not centrally disposed) and measured two minutes after being held in a bent state for a time period of at least 24 hours. The crease region includes the region of the foldable apparatus 10 proximate to the bend axis 102 (such that no local peaks in surface height where the surface height of the front surface is greater than that in unbent portions of the foldable apparatus are located in the crease region) where the front surface 12 exhibits the local minimum in surface height as well as portions of the foldable apparatus 10 exhibiting a surface height within 0.9*tₕ of the local minimum surface height. A particular point on the front surface 12 (see FIG. 1) is in the crease region if that point exhibits a surface height hi such that hi-hₘᵢₙ≤0.9*tₕ. The crease region includes a continuous portion of the foldable apparatus 10 associated with an area of the front surface 12 that is depressed in height as a result of the foldable apparatus being held in a bent state. Applicant has found that the second glass-based layer 102 described herein can substantially improve crease recovery rates for the stack if the glass-based layer 402 comprises a minimum thickness (at least 10 μm) throughout the entirety crease region. As such, in embodiments, the second glass-based layer 402 can comprise a continuous strip of glass-based material having a thickness of at least 10 μm throughout the entirety of the crease region. In aspects, when a elastic modulus of the second glass-based layer 402 is less than or equal to 80 GPa, the second glass-based layer 402 can comprise a continuous strip of glass-based material having a thickness of at least 30 μm (e.g., from 30 μm to 50 μm) throughout the entirety of the crease region. It is believed that ensuring a continuous volume of glass-based material of at least a minimum thickness in the crease region beneficially ensures that the crease recovers uniformly throughout the crease region. As such, embodiments where the second-glass based layer 402 lacks through-holes or cavities to ensure a continuous volume of glass-based material having at least the minimum thickness in the crease region can beneficial.

In aspects, the second glass-based layer 402 can be pre-warped (e.g., prior to assembly with the cover glass stack 102 and/or display panel 300) to counteract creasing. For example, the second glass-based layer 402 can be subjected to an asymmetric ion exchange treatment where one exhibits a surface compressive stress or depth of compression that is greater than that of the other side (such asymmetric ion exchange can result from one side of the second glass-based layer 402 being textured to a different extent than the other, such as if one surface exhibits an Sq value that is at least 5 nm greater than the second side). The side with greater surface compressive stress/depth of compression can be situated so that the second glass-based layer 402 counteracts creasing exhibited at the front surface 12 (see FIG. 1). That is the side with greater surface compressive stress/depth of compression can face the display panel 300. Alternatively, an opposite configuration could lower the bending force required to fold the foldable apparatus 10 from an open state.

FIG. 2B depicts an embodiment with an underside stack 400′ according to an alternative embodiment. Underside stack 400′ differs from underside stack 400 depicted in FIG. 2A in that the underside stack 400′ includes a second glass-based layer 402′ that comprises a reduced-thickness portion 420 so that the second thickness 414 occurs in the reduced-thickness portion 420. The reduced-thickness portion 420 can overlap the bend axis 102 (so that the fold plane 109 extends through the reduced-thickness portion 420). As shown, for example, the reduced-thickness portion 420 is symmetrically divided by the fold plane 109. A variety of forms of the reduced-thickness portion are contemplated. In an example, the reduced-thickness portion 420 can comprise a strip of the second glass-based layer 402′ having a reduced thickness as compared to the remainder of the second glass-based layer 402′. In aspects, the reduced-thickness portion 420 can have a thickness that is 20 μm less, 40 μm less 60 μm less, or any thickness difference lying in any range bounded by such values as inclusive endpoints, than that of the remainder of the second glass-based layer 402. In the depicted embodiment, in the reduced-thickness portion 420, a central portion of the first major surface 410 is recessed relative to the remainder of the first major surface 410 by a distance corresponding to a thickness difference between the second thickness 414 and a maximum thickness 422 of the second glass-based layer 402′. The reduced-thickness portion 420 can define a groove in a monolithic glass-based layer that faces the display substrate 304. Such a configuration can potentially reduce the tensile strains that the OLED display panel 300 is subjected to during bending by reducing the amount of glass-based material at the bend axis 102. An alternative configuration, in which the reduced-thickness portion 420 is formed via a recessed area of the second major surface 412 is also contemplated. In aspects, both the first and second major surfaces 410 and 412 are recessed to form the reduced-thickness portion 420. The shape of the second glass-based layer 402 when the reduced-thickness portion 420 is included can take any of the forms described in U.S. Pat. No. 12,207,539 B1, entitled “Foldable Substrates Having a Cavity Filled with a Polymer and Methods of Making,” filed on Jun. 10, 2024, and hereby incorporated by reference in its entirety. While not depicted in the Figures, the first glass-based layer 202 can also include a reduced-thickness portion in addition to or instead of the second glass-based layer 402.

In the example depicted in FIG. 2B, the reduced-thickness portion 420 has a width 424 measured in a direction parallel to the first major surface 410 (in the direction 106 shown in FIG. 1). The width 424 can include any regions of transition where the thickness of the second glass-based layer 402 transitions between the second thickness 414 and the maximum thickness 422. In aspects, the width 424 can be about 1 mm or more, about 3 mm or more, about 5 mm or more, about 8 mm or more, about 10 mm or more, about 15 mm or more, about 20 mm or more, about 100 mm or less, about 60 mm or less, about 50 mm or less, about 40 mm or less, about 35 mm or less, about 30 mm or less, or about 25 mm or less. The width 424 can be in a range from about 1 mm to about 100 mm, from about 3 mm to about 100 mm, from about 3 mm to about 60 mm, from about 5 mm to about 60 mm, from about 5 mm to about 50 mm, from about 8 mm to about 50 mm, from about 8 mm to about 40 mm, from about 10 mm to about 40 mm, from about 10 mm to about 35 mm, from about 15 mm to about 35 mm, from about 15 mm to about 30 mm, from about 20 mm to about 30 mm, from about 20 mm to about 25 mm, or any range of subrange therebetween. By providing a width within the above-noted ranges for the central portion (e.g., between the first portion and the second portion), folding of the foldable apparatus without failure can be facilitated.

In aspects, the second glass-based layer 402′ is formed of multiple pieces of glass-based material, as described in U.S. Patent Application Publication No. 2023/0370535A1, entitled “Foldable Apparatus and Methods of Making,” filed on Mar. 21, 2023, or U.S. Patent Application Publication No. 2021/0107251 A1, entitled “Foldable Apparatus and Methods of Making,” filed on Oct. 12, 2020, hereby incorporated by reference in their entireties.

In aspects where the second glass-based layer 402′ comprises a reduced-thickness portion, the second glass-based layer 402′ can comprise a polymer portion 426 disposed in the cavity defined by the recessed major surface. Suitable materials for the polymer portion 426 can be found in U.S. Pat. No. 12,207,539 B1, U.S. Patent Application Publication No. 2023/0370535A1, and U.S. Patent Application Publication No. 2021/0107251 A1. It is believed that replacing glass-based material with polymeric material of the polymer portion 426 can controllably reduce rigidity of the second glass-based layer 402 to aid in reducing bending-reduced strains in the OLED display panel 300.

FIG. 2C depicts an embodiment of the foldable apparatus 10 including another possible configuration. As shown, the embodiment depicted in FIG. 2C includes an underside stack 400″ that differs from the underside stack 400 described with respect to FIG. 2A in that, in FIG. 2C, the underside stack 400″ comprises a second glass-based layer 402″ that is segmented. That is, the second glass-based layer 402″ does not extend over an entirety of the display substrate 304, but is instead broken up into segments that are separated from one another by gaps 434 that are devoid of glass-based materials. Each of the segments is a separate portion of glass-based material. As shown, the embodiment depicted in FIG. 2C includes a central segment 430 overlapping the bend axis 102 and two off-center segments 432. The central segment 430 may be a strip of glass-based material having a width less than that of the display substrate 304 but covering an entirety of width 103 of the foldable apparatus 10. In example embodiments, the central segment 430 may have a width (in the direction 106 shown in FIG. 1) lying in any of the ranges provided herein for the width 424 of the reduced-thickness portion 420 described with respect to FIG. 2B. In aspects, the gaps 434 can be less than 25% of the width 103 (see FIG. 1). The gaps 434 may be filled with air or any of the polymer-based materials described herein. In some embodiments, the off-center segments 432 are omitted such that the second glass-based layer 402 only comprises the central segment 430. In aspects, the central segment 430 my not be centered with respect to the bend axis 102 (e.g., a widthwise center of the central segment 232 can be offset from the bend axis 102) though it may be advantageous in certain embodiments if the central segment 232 is centered on the bend axis 102 to distribute stresses throughout the bent portion of the OLED display panel 300.

Breaking up the second glass-based layer 402 into segments as depicted in FIG. 2C can decouple the bending stresses in the different regions of the foldable apparatus 10 containing differing amounts of glass-based material through the thickness. It is believed that such segmented designs can result in improved creasing performance (e.g., in terms of magnitude of creasing exhibited in the foldable apparatus after being held in a folded state for a period of 120 hours, as described in greater detail herein) as compared to designs with a second glass-based layer 402 that covers an entirety of the display substrate 304. Such segmented designs could also reduce the amount of force needed to fold the foldable apparatus 10 over embodiments such as those depicted in FIG. 2A. In aspects, the second glass-based layer 402 can be broken up into any suitable number of segments with any geometric arrangement.

Embodiments are envisioned where the different segments of the second glass-based layer 402 differ from one another in at least one of thickness and composition. For example, the central segment 430 could be formed of glass-based material that has a smaller elastic modulus than that used to form the off-center segments 432. Such a construction could beneficially add rigidity to non-bending portions of the foldable apparatus 10 (e.g., to potentially improve puncture resistance), without detrimentally effecting bending performance to a significant extent. In aspects the off-center segments 432 are not ion exchanged. The off-center segments 432 not being ion exchanged beneficially improves the fracture toughness of those segments and may also improve flatness.

FIG. 2D depicts another configuration of the foldable apparatus 10. The embodiment depicted in FIG. 2D includes an underside stack 400′″ that differs from the underside stack 400″ described herein with respect to FIG. 2C in that the underside stack 400′″ includes a second glass-based layer 402′″ that is segmented but includes no glass-based material overlapping the bend axis 102 (such that the fold plane 109 does not extend through any glass-based material of the underside stack 400′″). As shown in FIG. 2D, the second glass-based layer 402′″ includes two outer segments 440 that are separated from one another by a gap 442. The bend axis 102 overlaps the gap 442. In aspects, the gap 442 is an airgap. In aspects, the gap 442 may be filled with any of the polymeric materials described herein. The gap 442 may have a width lying in any of the ranges provided herein with respect to the reduced-thickness portion 420 described herein with respect to FIG. 2C. It is believed that the underside stack 400′″ depicted in FIG. 2D can be beneficial in that it can increase rigidity of un-bent portions of the OLED display panel 300 to potentially provide durability improvements. The two outer segments 440 can also aid in maintaining flatness of un-bent portions of the display panel 300, thereby improving image quality. The outer segments 440 could also serve any of the functions of the second glass-based layer 402 described herein with respect to FIG. 2A but not be stressed during bending. Such a lack of bending-induced stresses can provide flexibility in the construction of the second glass-based layer 402. For example, in aspects, the outer segments 440 may not be ion exchanged.

Referring more generally to FIGS. 2A-2D, in aspects, the cover glass stack 200 comprises multiple glass-based layers. For example, in addition to the first glass-based layer 202, the cover glass stack 200 can include an additional glass-based layer (not depicted). A layer of optically clear adhesive 206 may be disposed between the additional glass-based layer and the first glass-based layer 202. The additional glass-based layer may be the same thickness and composition as the first glass-based layer 202. The additional glass-based layer may enhance the puncture resistance exhibited by the foldable apparatus 10 from the front surface and also improve creasing performance in terms of a crease that is initially visible after the foldable apparatus 10 is held in the folded state. In aspects, the additional glass-based layer can be implemented as a removable screen protector.

As used herein, “foldable” includes complete folding, partial folding, bending, flexing, or multiple capabilities. As used herein, the terms “fail,” “failure” and the like refer to breakage, destruction, delamination, or crack propagation. A foldable apparatus achieves an effective bend radius of “X,” or has an effective bend radius of “X,” or comprises an effective bend radius of “X” if it resists failure when the foldable apparatus is held at “X” radius for 24 hours at about 85 °C and about 85% relative humidity. Likewise, a foldable apparatus achieves a parallel plate distance of “X,” or has a parallel plate distance of “X,” or comprises a parallel plate distance of “X” if it resists failure when the foldable apparatus is held at a parallel plate distance of “X” for 24 hours at about 85 °C and about 85% relative humidity.

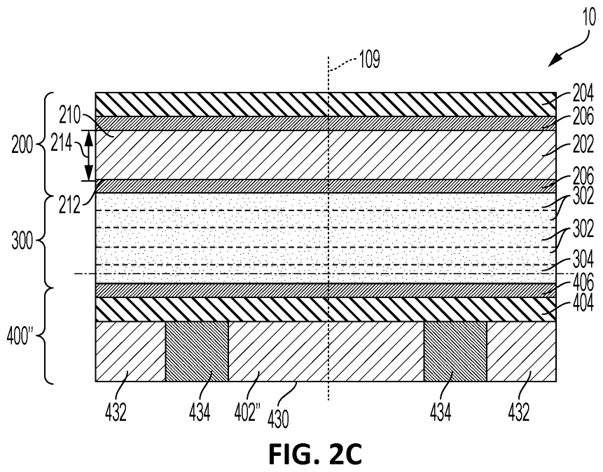

As used herein, the “effective minimum bend radius” and “parallel plate distance” of a foldable substrate is measured with the following test configuration and process using a parallel plate apparatus 801 (see FIG. 3) that comprises a pair of parallel rigid stainless-steel plates comprising a first rigid stainless-steel plate 803 and a second rigid stainless-steel plate 805. For determining a “parallel plate distance”, the distance between the parallel plates is reduced at a rate of 50 μm/second until the parallel plate distance 811 is equal to the “parallel plate distance” to be tested. Then, the parallel plates are held at the “parallel plate distance” to be tested for 24 hours at about 85 °C and about 85% relative humidity. As used herein, the “minimum parallel plate distance” is the smallest parallel plate distance that the foldable apparatus can withstand without failure under the conditions and configuration described above. For determining the “effective minimum bend radius”, the distance between the parallel plates is reduced at a rate of 50 μm/second until the parallel plate distance 811 is equal to twice the “effective minimum bend radius” to be tested. Then, the parallel plates are held at twice the effective minimum bend radius to be tested for 24 hours at about 85 °C and about 85% relative humidity. As used herein, the “effective minimum bend radius” is the smallest effective bend radius that the foldable apparatus can withstand without failure under the conditions and configuration described above.

In some embodiments, the foldable apparatus 10 can achieve a bend radius of 100 mm or less, 50 mm or less, 20 mm or less, 10 mm or less, 5 mm or less, or 3 mm or less. In further embodiments, the foldable apparatus 10 can achieve a parallel plate distance of 50 millimeters (mm), or 20 mm, or 10 mm, or 5 mm, or 3 mm, or 2 mm, or 1 mm. In some embodiments, the foldable apparatus 10 can comprise an effective minimum bend radius in a range from about 1 mm to about 40 mm, from about 1 mm to about 20 mm, from about 1 mm to about 10 mm, from about 1 mm to about 5 mm, from about 1 mm to about 3 mm, from about 3 mm to about 40 mm, from about 3 mm to about 40 mm, from about 3 mm to about 20 mm, from about 3 mm to about 10 mm, from about 3 mm to about 5 mm, from about 5 mm to about 10 mm, or any range or subrange therebetween.

In some embodiments, the foldable apparatus 10 can achieve a parallel plate distance of 100 mm or less, 50 mm or less, 40 mm or less, 30 mm or less, 20 mm or less, 10 mm or less, or 5 mm or less. In further embodiments, the foldable apparatus 10 can achieve a parallel plate distance of 50 millimeters (mm), or 40 mm, or 30 mm, or 20 mm, or 10 mm, or 5 mm, or 3 mm. In some embodiments, the foldable apparatus 10 can comprise an effective minimum parallel plate distance in a range from about 3 mm to about 50 mm, from about 5 mm to about 50 mm, from about 5 mm to about 40 mm, from about 8 mm to about 40 mm, from about 8 mm to about 30 mm, from about 10 mm to about 30 mm, from about 10 mm to about 20 mm, from about 15 mm to about 20 mm, or any range or subrange therebetween.

A minimum force may be used to achieve a predetermined parallel plate distance with the foldable apparatus. The parallel plate apparatus of FIG. 3 is used to measure the “closing force” or “bend clutch force” of a foldable apparatus of the embodiments of the disclosure. The force to go from the first configuration (e.g., see FIGS. 1-2) to the second configuration (e.g., see FIG. 3) comprising the predetermined parallel plate distance is measured. In some embodiments, the force per width 103 to bend the foldable substrate and/or the foldable apparatus from the first configuration comprising a bend angle of about 100° to a parallel plate distance of 10 mm can be about 20 Newtons per millimeter (N/mm) or less. In some embodiments, the force per width 103 to bend the foldable substrate and/or the foldable apparatus from the first configuration comprising a bend angle of about 100° to a parallel plate distance of 10 mm can be in a range from about 0.001 N/mm to about 20 N/mm.

The foldable apparatus 10 may be further characterized by the amount of creasing exhibited at the front surface 12. The creasing can be quantified by calculating an optical distortion proximate to the bend axis 102 by directing an image having parallel lines thereon, after the foldable apparatus 10 is held for 120 hours at a given parallel plate distance and then released. Methods for quantifying creasing are described in U.S. Provisional Patent Application No. 63/742,163, entitled “Bendable Devices and Cover Materials for Bendable Devices,” filed on Jan. 6, 2025, hereby incorporated by reference in its entirety. Unless otherwise noted, recitation of optical distortion for creasing at the bend axis 102 is the mean curvature along a line profile extending in the direction 106 (see FIG. 1) across the fold plane 109. The line extends 25 mm in the direction 106 on either side of the fold plane 109 (i.e., only the 50 mm closest to the center of the hinge are considered). Details on the measurement method for the optical distortion can be found in Lindberg, K. A., Pikula, D., & Banerjee, J., “Quantitative Assessment of Hinge Creases in Folding Devices,” 77-5: Late-News Paper, SID Symposium Digest of Technical Papers (Vol. 56, No. 1, pp. 1057-1059), published June 2025, hereby incorporated by reference in its entirety.

In aspects, after the foldable apparatus 10 is bent for 120 hours and then unbent, the front surface 12 comprises an optical distortion at the bend axis 102 (e.g., within 20 mm of the bend axis) in a range from about 1 diopters to about 30 diopters. Unless otherwise noted, the optical distortion values provided herein are at an observation time of 24 hours after release. Optical distortion values herein are measured as measured by a phase deflectometry system (available from ISRA VISION GmbH, Dramstadt, Germany, under the trade name ISRA SpecGage3D), with 0.3 mm pixel size. For example, the optical distortion at bend axis 102 may be in a range from about 1 diopters to about 28 diopters, from about 1 diopters to about 26 diopters, from about 1 diopters to about 25 diopters, from about 1 diopters to about 24 diopters, from about 1 diopters to about 22 diopters, from about 1 diopters to about 20 diopters, from about 1 diopters to about 18 diopters, from about 1 diopters to about 16 diopters, from about 1 diopters to about 15 diopters, from about 1 diopters to about 14 diopters, from about 1 diopters to about 12 diopters, from about 1 diopters to about 10 diopters, from about 1 diopters to about 8 diopters, from about 1 diopters to about 5 diopters, from about 2 diopters to about 30 diopters, from about 4 diopters to about 30 diopters, from about 5 diopters to about 30 diopters, from about 6 diopters to about 30 diopters, from about 8 diopters to about 30 diopters, from about 10 diopters to about 30 diopters, from about 12 diopters to about 30 diopters, from about 14 diopters to about 30 diopters, from about 15 diopters to about 30 diopters, from about 16 diopters to about 30 diopters, from about 18 diopters to about 30 diopters, from about 20 diopters to about 30 diopters, from about 22 diopters to about 30 diopters, from about 24 diopters to about 30 diopters, from about 5 diopters to about 20 diopters, from about 10 diopters to about 15 diopters, from about 12 diopters to about 17 diopters, or any ranges and sub-ranges therebetween.

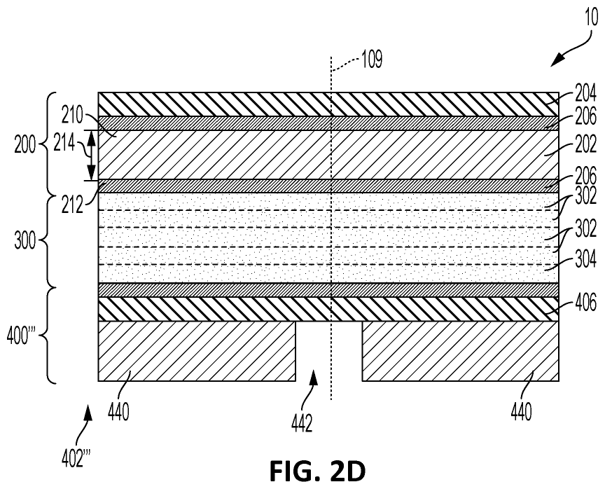

The foldable apparatus 10 can be further characterized by a puncture resistance. An example of how puncture resistance can be measured is via the pen drop apparatus 1401 depicted in FIG. 4. The pen drop apparatus 1401 includes a ballpoint pen 1403, which is a BIC Easy Glide Pen, Fine comprising a ballpoint tip 1405 of 0.7 mm (0.68 mm) diameter made of tungsten carbide, and a weight of 5.73 grams (g) including the cap. The ballpoint pen 1403 is held at a predetermined height 1409 from the front surface 12 of the foldable apparatus 10. A tube (not shown for clarity) is used as part of the pen drop apparatus 1401 to guide the ballpoint pen 1403 to the front surface 12, and the tube is placed in contact with the front surface 12 so that the longitudinal axis of the tube is substantially perpendicular to the outer major surface with the longitudinal axis of the tube extending in the direction of gravity. The tube has an outside diameter of 1 inch (2.54 cm), an inside diameter of nine-sixteenths of an inch (1.4 cm), and a length of 90 cm. An acrylonitrile butadiene (“ABS”) shim (not shown) is employed to hold the ballpoint pen 1403 at a predetermined height 1409 for each test.

For the Pen Drop test, the ballpoint pen 1403 is dropped with the cap attached to the top end (i.e., the end opposite the ballpoint tip 1405) so that the ballpoint tip 1405 can interact with the test sample (e.g., front surface 12). In a drop sequence according to the Pen Drop, one pen drop is conducted at an initial height of 1 cm, followed by successive drops in 0.5 cm increments up to 20 cm, and then after 20 cm, 2 cm increments until failure of the test sample. After each drop is conducted, the presence of any observable fracture, failure, or other evidence of damage to the sample is recorded along with the particular pen drop height. After each drop, the tube is relocated relative to the outer surface of the sample to be tested to guide the ballpoint pen 1403 to a different impact location on the outer surface of the sample to be tested. The ballpoint pen is changed to a new pen after every 5 drops, and for each new multilayer apparatus tested. In addition, all pen drops are conducted at random locations on the front surface with no pen drops near or on the edge of the sample. Using the Pen Drop test, multiple samples can be tested according to the same drop sequence to generate a population with improved statistical accuracy.

For purposes of the Pen drop test, “failure” means the formation of a visible mechanical defect in a laminate. The mechanical defect may be a crack or plastic deformation (e.g., surface indentation). The crack may be a surface crack or a through crack. The crack may be formed on an interior or exterior surface of the foldable apparatus 10. The crack may extend through all or a portion of the multilayer apparatus. A visible mechanical defect has a minimum dimension of 0.2 mm or more.

In aspects, in the Pen Drop test, the front surface 12 can resist failure for a pen drop at a pen drop height of 10 centimeters (cm), 12 cm, 14 cm, 16 cm, 18 cm, 20 cm, 21 cm, 22 cm, 23 cm, 24 cm, or 25 cm. As used herein, a “threshold height” is the maximum pen drop height that the foldable apparatus can withstand without failure. In aspects, the threshold height (e.g., pen drop threshold height in the Pen Drop for. In aspects, a pen drop threshold height can be in a range from about 12 cm to about 40 cm, from about 14 cm to about 40 cm, from about 16 cm to about 35 cm, from about 18 cm to about 35 cm, from about 20 cm to about 30 cm, from about 21 cm to about 28 cm, from about 22 cm to about 25 cm, or any range or subrange therebetween.

Another method of measuring puncture resistance is a Quasi-Static Puncture test. In the Quasi-Static Puncture test, a tungsten carbide ball with a predetermined diameter (e.g., 0.5 mm) is placed on the front surface and pressed into the front surface 12 at a rate of 0.5 mm/min until failure. Unless otherwise indicated, the predetermined diameter of the tungsten carbide ball is 0.5 mm. The front surface 12 can exhibit a puncture resistance as measured in a Quasi-Static Puncture Test of 2.0 kgf or more, 2.5 kgf or more, 3.0 kgf or more, 3.5 kgf or more, 4.0 kgf or more, 4.2 kgf or more, 4.4 kgf or more, 4.5 kgf or more, 4.6 kgf or more, 4.7 kgf or more, 4.8 kgf or more, 4.9 kgf or more, 5.0 kgf or more.

### Examples

Embodiments of the present disclosure may be further understood in view of the following Examples.

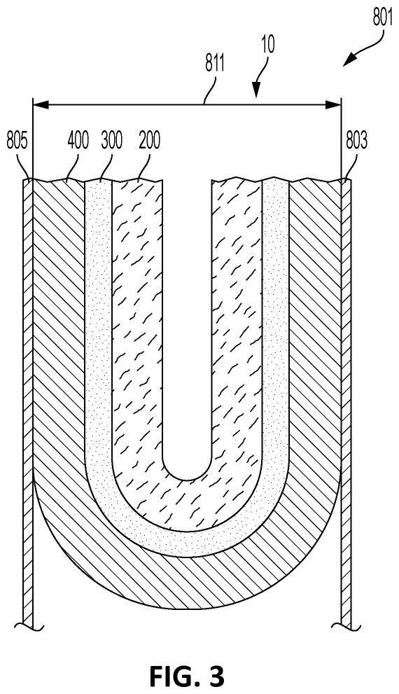

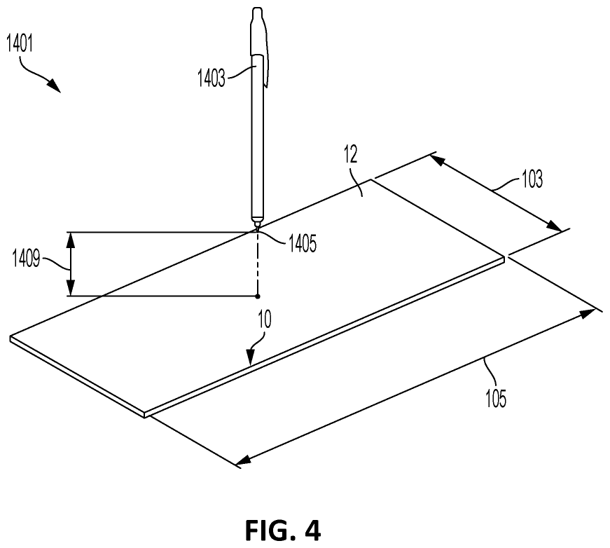

Modelling was conducted to determine the performance of various example foldable apparatus structures depicted in FIGS. 5 and 6A-6E. In the modelling described herein, perfect bonding conditions were assumed at all interfaces between adjacent layers (adhesive layers are omitted). Each of the modelled structures included a display surrogate 1501 for an OLED display panel comprising two 50 μm layers of polyethylene terephthalate (Elastoplastic, E-3.3 GPa, v=0.35, ε_{Y}=2.14%) separated by a 25 μm layer of optically clear adhesive (hyperplastic, E-0.4 MPa, v=0.48). The surrogate 1501 includes a 50 μm thick layer of the same layer of optically clear adhesive to attached the display surrogate 1501 to the cover glass stack. FIG. 5 is a comparative example without an underside glass stack and where the cover glass stack comprises a single layer of bendable glass sold by Corning® Incorporated (Linearly-elastic, E=78 GPa, v=0.22). Unless otherwise noted, the glass-based layers of the Examples have a thickness (corresponding to the first and second thicknesses 214 and 414 described herein) of 40 μm. FIG. 6A is Example 1, where the underside stack comprises a second glass-based layer and a 50 μm thick layer of the optically clear adhesive. FIB. 6B is Example 2, where the underside stack comprises an embodiment in accordance with FIG. 2B, such that the recess faces away from the OLED display panel. The maximum thickness of the second glass-based layer is 100 μm. FIG. 6C is Example 3, which has a similar configuration as Example 2, but the recess faces the opposite direction. FIG. 6D is Example 4, where the underside stack is configured as described herein with respect to FIC. 2C. FIG. 6E is Example 5, where there is no underside stack and the cover glass stack comprises an additional glass-based layer with a 25 μm thick layer of the optically clear adhesive.

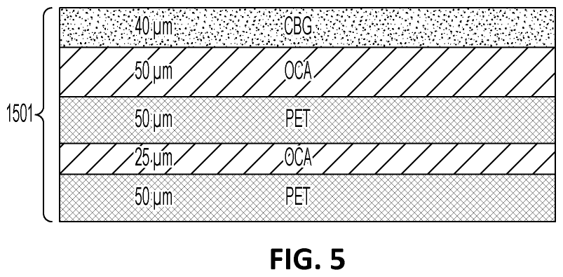

The amounts of strain were throughout the display surrogate 1501 were modelled when each apparatus was held at a parallel plate distance of 3 mm. The results are depicted in FIG. 7. The numerical details are also provide in Table 1.

TABLE 1

Strain (%)

| Case | Compression | | | Tension | | |
|---|---|---|---|---|---|---|
| CE1 | | | −2.06 | | | 2.91 |
| E1 | | −2.46 | ↑ | | 2.41 | ↓ |
| E2 | −2.57 | ↑ | ↑ | 2.51 | ↑ | ↓ |
| E3 | −2.57 | ↑ | ↑ | 2.23 | ↓ | ↓ |
| E4 | −2.25 | ↓ | ↑ | 2.91 | ↑ | → |
| E5 | −2.03 | ↓ | → | 2.91 | ↑ | → |

As shown, in terms of compressive strain, each of the Examples resulted in a higher maximum compressive strain within the OLED display panel as compared to Counter Example 1. However, in terms of tensile strain, Examples 1-3 each significantly lowered the maximum tensile strains in the OLED display panel. These results indicate that an underside stack including a second glass-based layer can beneficially lower maximum tensile strain and potentially prevent failure of display panel componentry.

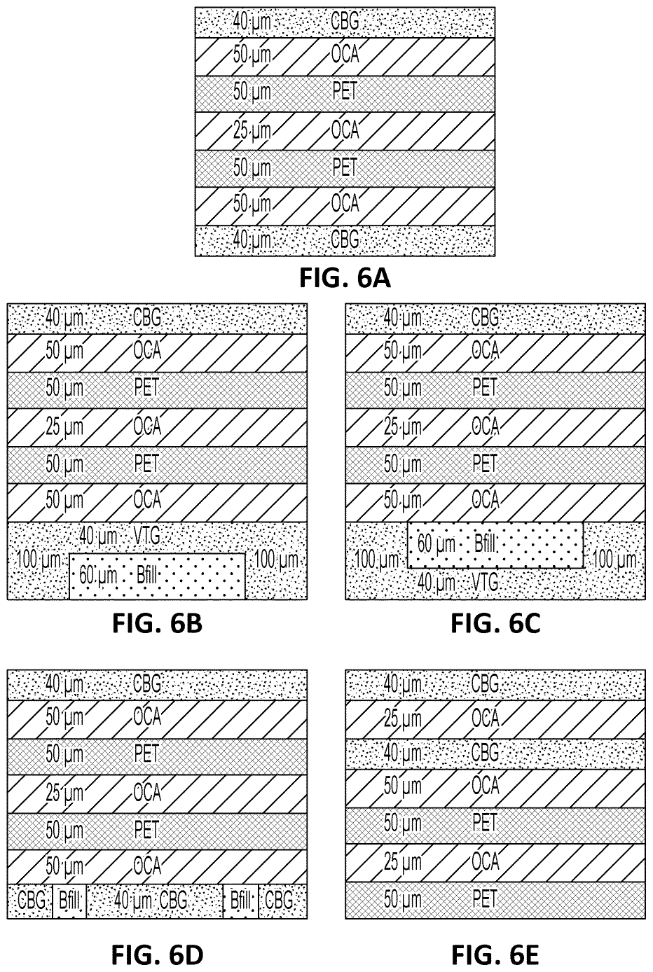

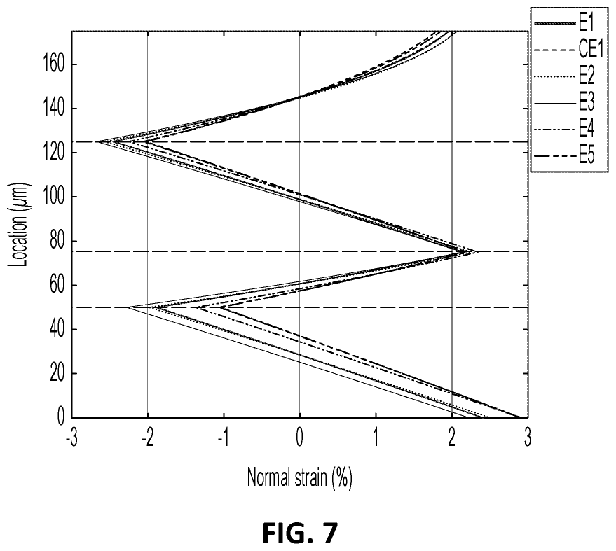

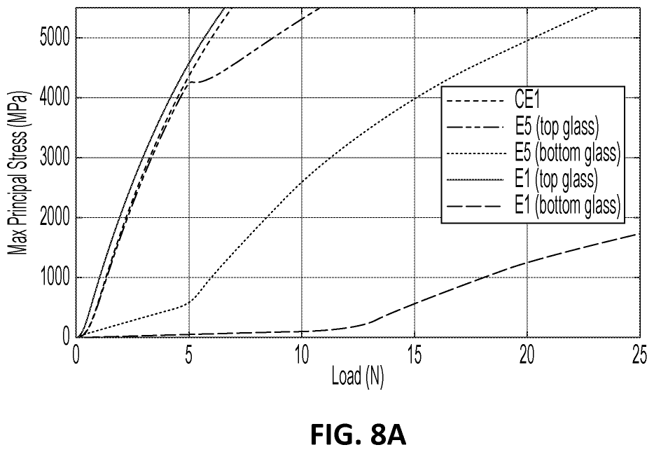

Performance of each of the stacks was also modelled in the Quasi Static Puncture test described herein. Counter Example 1, Example 5, and Example 1 were tested. The resulting max principle stress results in each of the glass-based layers are shown in FIG. 8A. As shown, Example 5 and Counter Example 1, result in almost same Max principal stress vs load curve until glass layers make contact. Example 5, with the additional glass-based layer has a potential to improve QSP load by 46% (assume MTG strength is about 5 GPa) due to the support provided by the bottom glass-based layer. Example 1 (top glass) showed comparable results to that in the counter example, indicating little detrimental impact to puncture resistance caused by the second glass-based layer of the underside stack. FIG. 8B plots the results for normal stress from the puncture test in each of the layers in the display surrogate 1501. As shown, Example 5 results in lower overall stress in the display, indicating a protective effect of the additional glass-based layer. The maximum stress values in Example 1 were comparable to those in the Counter Example. FIG. 8C plots the results for shear strain from the puncture test in each of the layers in the display surrogate 1501. As shown, Example 5 results in a much lower shear strain in the display panel compared to the other examples, indicating the efficacy of the additional glass layer in puncture test performance. Moreover, the maximal shear strain values for Example 1 were about 20% lower than in the Counter Example. These results indicate that the additional glass-based layers described herein can improve puncture performance not only in terms of stress on the glass-based layer, but also in terms of the magnitude of strains that layers of the display panel are subjected to.

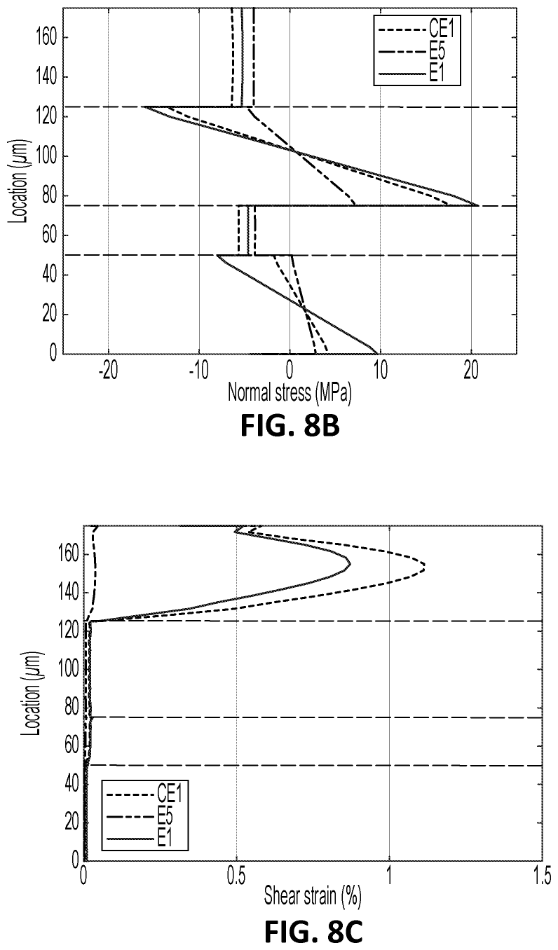

Creasing performance of each of the Examples was also modelled using the apparatus 1600 depicted in FIGS. 9A-9B. In the apparatus 1600, the foldable apparatus 10 is adhered to a support 1601 via an adhesive layer 1608. The support includes a first portion 1602 adhered to the foldable apparatus 10 on a first side of the bend axis by a first portion of the adhesive layer 1608 and a second portion 1604 adhered on a second side of the bend axis by a second portion of the adhesive layer 1608. The first and second portions 1602 and 1604 are rotatable about pivots 1603 and 1605, respectively. The portions of the adhesive layer 1608 only extend along portions of the foldable apparatus 10 so that there is a non-adhered length 1610 of 80 mm across the bend axis, with the bend axis being centered along the non-adhered length 1610. The non-adhered length 1610 allows the creasing to occur. As shown in FIG. 6B, to measure the creasing, the first and second portions 1602 and 1604 are rotated about the pivots 1603 and 1605 so that the plates have a parallel plate distance 1612 of 3 mm. The foldable apparatus 10 is held in the state depicted in FIG. 9B for 120 hours, at which the apparatus 1600 returns to the state depicted in FIG. 9A and the shape of the foldable apparatus 10 is modeled to quantify creasing performance.

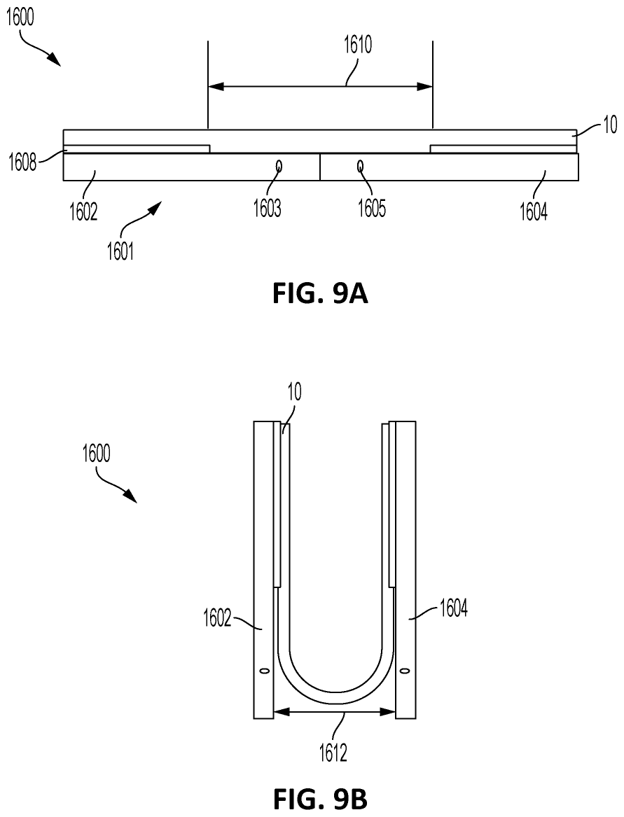

The results of the creasing performance modelling are provided in FIGS. 10A-10B, in terms of a modelled shape of the front surface 12 of the foldable apparatus 10. FIG. 10A shows the modelled shape right after the foldable apparatus 10 is returned to the planar shape (2 minutes after release). FIG. 10B shows the modelled shape after 24 hours of remaining in the planar shape. As shown in FIG. 10A, in terms of deviation from planarity, the Counter Example, Example 5, and Example 4 performed the best in terms of initial crease height, with Example 5 exhibiting the lowest initial crease height. As used herein, the term “crease height” refers to a difference between the maximum and minimum surface heights of a front surface of the foldable apparatus.

As shown in FIG. 10B, however, the Examples 1-3 each recovered to a greater extent after 24 hours than did the other examples. Indeed, in Example 1, the crease height decreased by more than 40% over the 24 hour observation period, which is larger than the recovery exhibited by the counter example. In terms of creasing performance, it appears that embodiment described herein with respect to FIG. 2C may over the best performance in terms of a combination of initial crease height and crease recovery. These results demonstrate that providing glass-based material of the second glass-based layer at the bend axis 102 (so that the fold plane 109 intersects glass-based material of the second glass-based layer) is beneficial from a crease recovery performance perspective, with each of such embodiments exhibiting a 40% crease height recovery (i.e., crease height after 24 hours/initial crease height is <0.4).

Embodiments of the present disclosure may be further understood in view of the following information.

FIGS. 11A and 11B depict a foldable device 1100 incorporating the foldable apparatus 10 according to any of the embodiments described herein with respect to FIGS. 1-3. As shown, the foldable device 1100 includes a housing 1102 to which the foldable apparatus 10 is attached (either directly by an adhesive disposed between the foldable apparatus 10 and the housing 1102 or indirectly by attachment to other components of the foldable device 1100 to which the foldable apparatus 10 is attached). The housing 1102 includes a first member 1104, a second member 1106, and a hinge structure 1108. The first and second members 1104 and 1106 are connected to one another by the hinge structure 1108. The hinge structure 1108 comprises any suitable mechanical structure (e.g., geared hinge mechanism, rotating hinge, flexible structure) that is capable of providing a pivot axis 1110. In aspects, the first member 1104 may be overlaid by a first portion 20 of the foldable apparatus 10 (see FIG. 11B) and the second member 1106 may be overlaid by the second portion 30 of foldable apparatus 10 (see FIG. 11B). The housing 1102 can be constructed to maintain a planar shape of the front surface at the first and second portions 20 and 30 irrespective of the operational state of the foldable device 1100 (i.e., folded or unfolded) to render high-quality images to the user.

The second member 1106 is configured to be movable with respect to the first member 1104 along the direction 1112 via the pivot axis 1110. Rotating the first and second members 1104 and 1106 relative to each other can alter a relative angle A that portions of the front surface 12 of the foldable apparatus extend relative to one another. The housing 1102 may be configured so that the foldable device 900 is reversibly reconfigurable between an open configuration, in which the angle A is approximately 180°, and a closed configuration, where the angle A is approximately 0°, in which the foldable apparatus 101 is in a configuration where the first and second portions 20 and 30 extend parallel to one another (or substantially parallel one another, such that the portions of a front surface 12 of the foldable apparatus (see FIG. 2A) extend within 5°, 4°, 3°, 2°, or 1° of one another). Unless otherwise noted herein, the “closed configuration” refers to the positioning of the housing when the angle A possess a minimum value, which can be negative (e.g., when different portions of the foldable apparatus 101 or the housing 902 contact one another to prevent further folding).

FIG. 11B depicts a side view of the foldable device 1100 when in the closed configuration, according to an example embodiment. The construction of the housing 1102 (e.g., via rigidity of various portions thereof and the manner with which the foldable apparatus 10 is attached thereto) can determine the shape that foldable apparatus 10 takes when the foldable device 1100 is placed in the closed configuration. In the example shown, the foldable apparatus 10 comprises a bent portion 40 when the foldable device 1100 is in the closed configuration. The bent portion 40 is defined by a portion of the front surface 12 that, as a result of being bent when the foldable device 1100 is in the closed configuration, deviates in shape from what it takes in the open configuration. That is, bending the foldable apparatus 10 causes the bent portion 40 to change shape at the front surface 12. As shown, a transition region 1113 is a location where the front surface 12 begins to exhibit curvature from the foldable apparatus 10 being bent when the foldable device 1100 is placed in the closed configuration.

The bent portion 40 is depicted to exhibit a waterdrop shape in the depicted example. Such a waterdrop shape is characterized by a trend of a distance 1114 between portions of the front surface 12 on either side of an axis 1116 extending through and perpendicular to the bend axis 102 about which the bent portion 40 is folded (the axis 1116 is in the fold plane 109 described elsewhere herein). Specifically, the distance 1114 increases with increasing distance from the transition region 1113 along the axis 1116 towards the bend axis 102. Put differently, over a portion of the bent portion 40, the distance 1114 increases with increasing distance from the transition region 1113. Such a waterdrop configuration is beneficial because it permits the first and second portions 20 and 30 to be placed closer to one another when the foldable device 1100 is in the closed configuration while maintaining bending-induced stresses on the foldable apparatus 10 at lower levels than if the bent portion 40 were bent in an elliptical or cylindrical configuration. As shown in FIG. 11B, the first and second portions 20 and 30 are situated to exhibit a minimum distance 1118 that is smaller than a maximum value of the distance 1114 between portions of the front surface 12 of the bent portion 40. Using a waterdrop configuration results in a minimum bend radius of the front surface 12 that is higher than if the bent portion 40 were bent in an elliptical configuration or constant radius configuration shown in FIG. 3. As a result, the waterdrop configuration allows a smaller minimum distance 1118 to be achieved at a given level of bending-induced stresses. Constructing the hinge structure 1108 of the housing 1102 to permit such a waterdrop shape (e.g., via reduced stiffness proximate to the transition 1113 and appropriate length of the hinge structure 1108) beneficially can also beneficially reduce the bending clutch force needed to place the foldable device 1100 in the closed configuration.

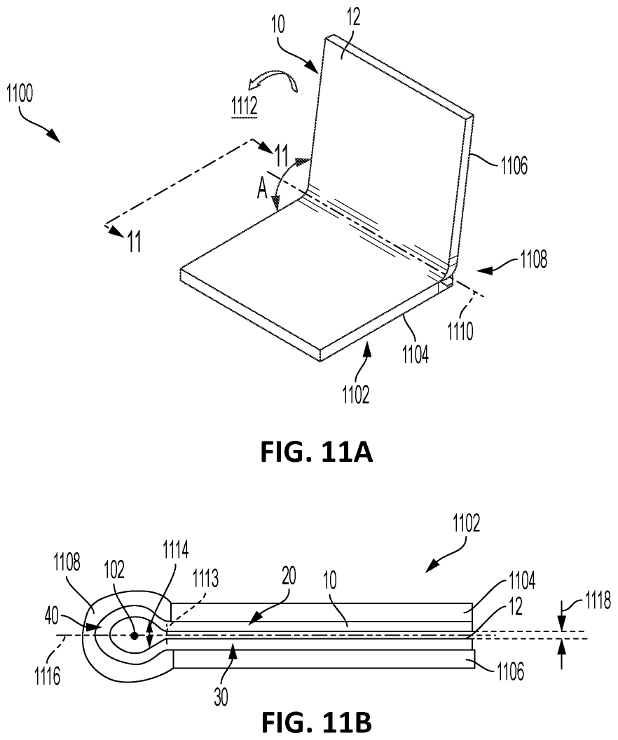

Applicant has found the second glass-based layer 402, 402′, 402″, and 402′″ of any of the underside stacks 400, 400′, 400″, and 400′″ described herein to be particularly beneficial from a crease-reduction perspective when the foldable apparatus 10 is bent to exhibit a waterdrop shape when the minimum distance 1118 is relatively low (e.g., less than or equal to 2.0 mm). Applicant modelled the additional foldable apparatus structures depicted in FIGS. 12A and 12B. Perfect bonding was assumed between the OLED layer and the second glass-based layers (while the figures do not show an adhesive layer, an adhesive layer may be present in a physical implementation). FIG. 12A depicts Counterexample 2 (thickness values in μm), which includes a PET layer behind the display panel as an underside stack (i.e., no second glass-based layer). FIG. 12B depicts Example 6, which had a configuration of the underside stack 400 described herein with respect to FIG. 2A (without the additional layer 404). Assumed properties of each layer for the modelling are provided in the Table 2.

TABLE 2

| | | |
|---|---|---|
| Layer | Elastic Modulus | Poisson's Ratio |

| | | | |
|---|---|---|---|
| CBG (Amorphous Glass) | 72 | GPa | 0.22 |
| OCA | 0.05 | MPa | 0.33 |
| Polarizer | 37350 | MPa | 0.33 |
| Touch Pad | 2600 | MPa | 0.31 |
| TFE | 3200 | MPa | 0.22 |
| AMOLED | 9100 | MPa | 0.33 |
| PET | 4600 | MPa | 0.32 |

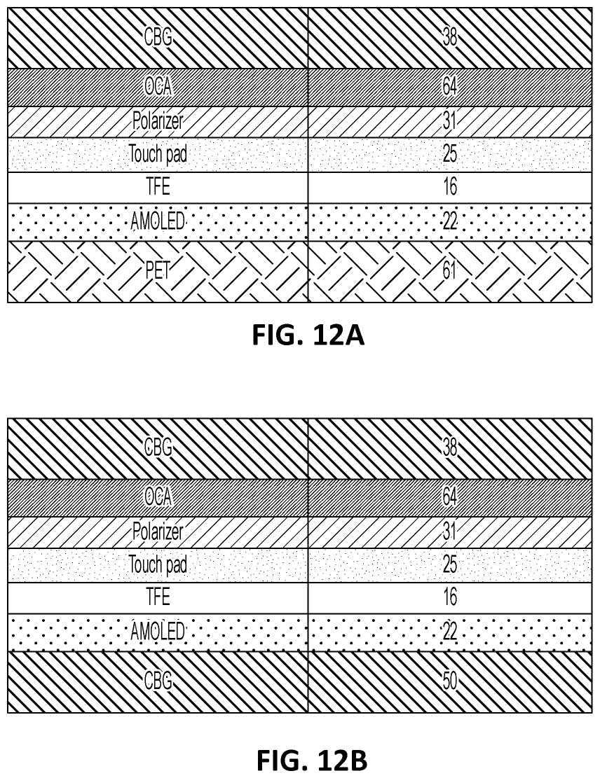

Loading dependent effects were introduced by assuming the CBG and OCA layers to be viscoelastic and the PET layer to be elastoplastic. Bending performance was modelled using the apparatus 1300 depicted in FIGS. 13A-13B. In the apparatus 1300, the foldable apparatus 10 is adhered to a support 1301 via an adhesive layer 1308. The support 1301 includes a first portion 1302 adhered to the foldable apparatus 10 on a first side of the bend axis by a first portion of the adhesive layer 1308 and a second portion 1304 adhered on a second side of the bend axis by a second portion of the adhesive layer 1308. The first and second portions 1302 and 1304 are movable relative to one another to bend the foldable apparatus in the waterdrop shape depicted in FIG. 13B. In FIG. 13A, the first and second portions 1302 and 1304 are separated from one another by a separation distance 1310 in a direction perpendicular to the fold axis to permit the portion of the foldable apparatus 10 not adhered to the support to bend. The separation distance 1310 can be any value above 20 mm. Unless otherwise noted, a separation distance of 26 mm was used in modelling Counterexample 2 and Example 6. The foldable apparatus 10 is held in the state depicted in FIG. 13B for 24 hours, at which point the apparatus 1300 returns to the state depicted in FIG. 13A and the shape of the foldable apparatus 10 is modeled to quantify creasing performance. As shown in FIG. 13B, the foldable apparatus 10 was bent to exhibit a minimum separation distance 1312 of 1.3 mm. In the modelling, the adhesive layer 1308 was assumed to be a 100 μm layer thick of pressure sensitive adhesive (having an elastic modulus of 45 MPa and a Poisson's ratio of 0.49).

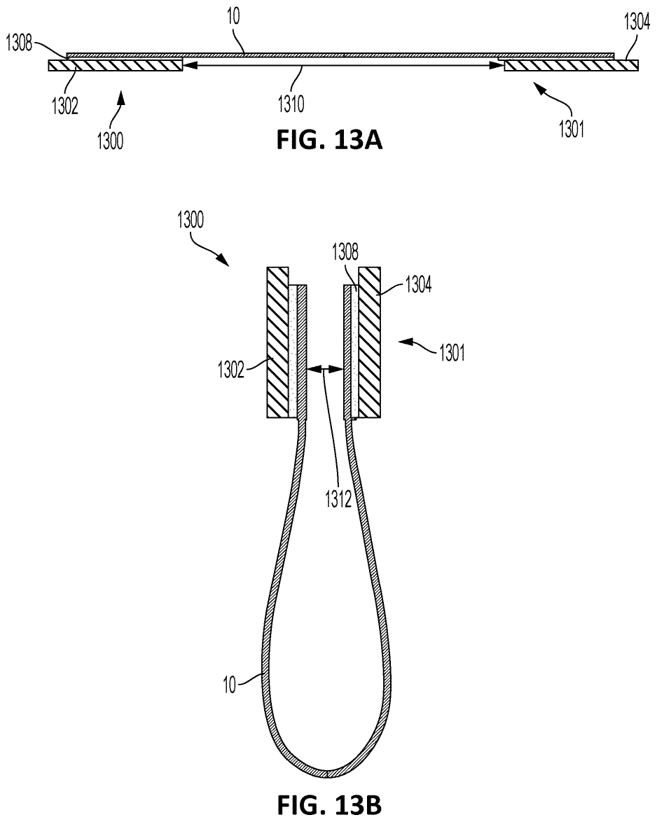

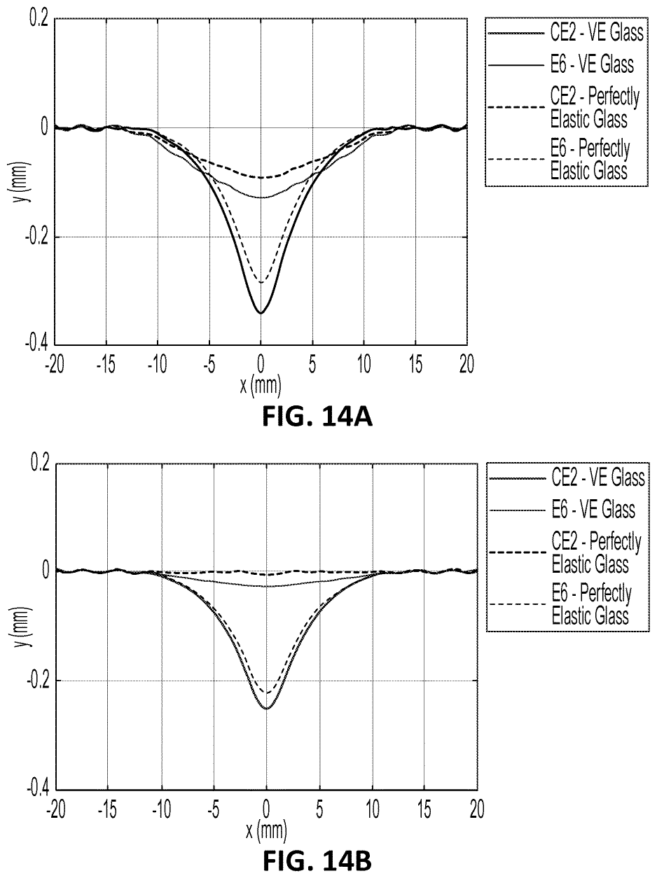

FIGS. 14A and 14B plot simulated front surface geometries 2 minutes and 24 hours after being returned to an open configuration, respectively. The simulation was performed both considering the viscoelastic properties of the glass-based layers and assuming the glass layers were perfectly elastic. The viscoelastic properties of the glass had relatively small effect. As shown in FIG. 14A, soon after being returned to the open configuration, Example 6 exhibited a much smaller deviation from flatness than Counterexample 2. The optical distortion after 2 minutes was estimated to be about 18.9 D for Example 6 for the elastic glass case and 26.5D for the viscoelastic glass case. These estimates were well under 50% of those exhibited by Counterexample 2 (Counterexample 2 exhibited an estimated distortion of about 65 D for the elastic glass case). Moreover, as shown in FIG. 14B, Example 6 also exhibited superior crease recovery. After 24 hours, Example 6 substantially recovered its original geometry prior to being held in the bent state (less than 40% of the initial crease height remained). Counterexample 2, in contrast, still retained substantial deformation after 24 hours. As such, when bent to a waterdrop configuration, the additional stiffness provided by the underside stacks described herein substantially improves creasing performance. It is believed that creasing performance could be further improved by increasing the elastic modulus of the second glass-based layer.

The amounts of strain were throughout the stacks shown in FIGS. 12A-12B were modelled when each apparatus was held in the configuration depicted in FIG. 13B. The results are shown in FIG. 14C. As shown, in terms of compressive strain, Example 6 resulted in a higher compressive strain within the display component layers than Counterexample 2. However, the additional glass-based layer significantly lowered the tensile strains proximate to the AMOLED layer. These results indicate that an underside stack including a second glass-based layer can beneficially lower maximum tensile strain and potentially prevent failure of display panel componentry. Moreover, as shown in FIG. 14C, the neutral axis that is most distance from the glass surface occurs at a depth of about 210 μm for Example 6, whereas this neutral axis is at a depth of about 165 μm in Counterexample 2. As such, the second glass-based layer facilitates placement of the neutral axis relatively close to the AMOLED layer in the waterdrop configuration, while lowering tensile bending stress.

Also of note is that the second glass-based layer was estimated to exhibit a maximum bending-induced stress of under half of that exhibited in the first glass-based layer. These results indicate that the second-glass-based layer can have less demanding ion exchange requirements to exhibit the requisite minimum parallel plate distance for a given design. The modelling results are summarized in the Table 3 below.

TABLE 3

| | E6 | CE2 |
|---|---|---|
| Distortion due to | 18.9 | 65.0 |
| waterdrop | | |
| creasing [D] | | |
| (Elastic Glass, | | |
| t = 2 min) | | |
| Bend force [N] | 19.5 | 9.4 |
| @WD1.3 mm | | |
| Glass stress | 447 (back glass) | 505 |
| (MPa) | 987 (front glass) | |
| @WD1.3 mm | | |

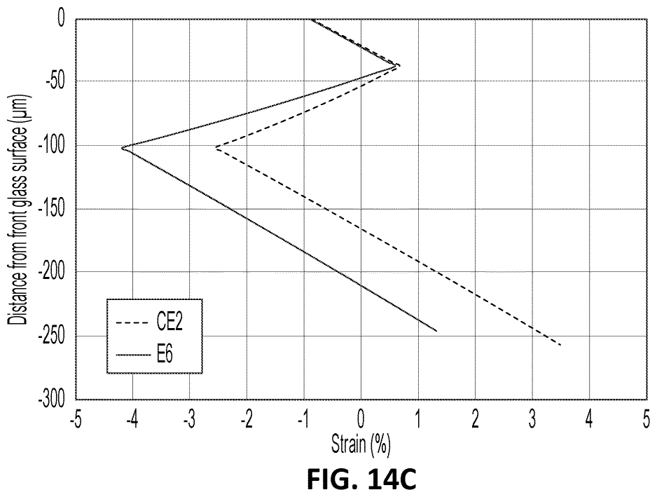

Referring now to FIG. 15, any of the second glass-based layers 402, 402′, 402″, and 402′″ (or any segment thereof) described herein can be replaced with a composite article 1500. The composite article 1500 comprises a glass-based layer 1510 and a second layer 1520. In aspects, the second layer 1520 is not formed of a glass-based material. The glass-based layer 1510 comprises a first major surface 1512, a second major surface 1514, and a thickness 1516 extending between the first major surface 1512 and the second major surface 1514. The glass-based layer 1510 can be constructed from glass-based material described herein with respect to the second glass-based layers 402, 402′, 402″, and 402″. In aspects, the thickness 1516 can be 5 μm, 10 μm, 15 μm, 20 μm, 25 μm, 30 μm, 35 μm, 40 μm, 45 μm, 50 μm, 55 μm, 60 μm, 65 μm, 70 μm, 75 μm, 80 μm, 85 μm, 90 μm, 95 μm, 100 μm, or any thickness lying in any range bounded by any two the preceding values as inclusive endpoints (e.g., from 10 μm to 100 μm, from 10 μm to 60 μm, from 20 μm to 40 μm, from 10 μm to 20 μm, etc.).

The second layer 1520 is a layer that is not glass-based and configured to impart stiffness to the glass-based layer 1510. The second layer 1520 can be formed of a material that exhibits an elastic modulus that is at least 10 GPa greater than the second layer 1520. The higher modulus of the second layer 1520 can beneficially enable the composite article 1500 to exhibit a higher effective elastic modulus (calculated as 1/E_{eff}=V_{g}/E_{g}+Vₛ/Eₛ, where V_{g} and Vₛ are the volume fraction of the glass-based and second layers, respectively) than in embodiments where the second glass-based layers second glass-based layers 402, 402′, 402″, and 402′″ are formed of a monolithic layer of a single glass-based material at a given thickness. Such a higher overall modulus can even be exhibited at a lower overall thickness 1550 than if the second glass-based layers are formed uniformly of a glass-based material. Adding the second layer 1502 can beneficially reduce the form factor of the underside stacks while still providing the same benefits from a crease recovery and tensile strain standpoint. In aspects, the overall thickness 1550 can be 10 μm, 15 μm, 20 μm, 25 μm, 30 μm, 35 μm, 40 μm, 45 μm, 50 μm, 55 μm, 60 μm, 65 μm, 70 μm, 75 μm, 80 μm, 85 μm, 90 μm, 95 μm, 100 μm, 125 μm, 150 μm, or any thickness lying in any range bounded by any two the preceding values as inclusive endpoints (e.g., from 10 μm to 100 μm, from 10 μm to 60 μm, from 20 μm to 40 μm, etc.). However, it is believed that, given the increased elastic response provided by the second layer 120, the overall thickness can be less than or equal to 50 μm, less than or equal to 30 μm, or even less than or equal to 20 μm while still providing the same crease recovery benefits as if a 50 μm monolithic layer of glass-based material were used.

In aspects, the second layer 1520 can comprise an inorganic material (and/or consist of inorganic materials). As used herein, inorganic materials are free of carbon-carbon bonds. Examples of suitable materials for the second layer 1520 include metal oxides, metal nitrides, metal oxynitride, metal carbides, metal oxycarbides, and/or combinations thereof. Exemplary metals include B, Al, Si, Ti, V, Cr, Y, Zr, Nb, Mo, Sn, Hf, Ta and W. Specific examples of materials that may be utilized in the second layer 1520 may include Al₂O₃, AlN, AlOₓN_{y}, Si₃N₄, SiOₓN_{y}, SiᵤAlᵥOₓN_{y}, diamond, diamond-like carbon, SiₓC_{y}, SiₓO_{y}C_{z}, ZrO₂, TiOₓN_{y}, or combinations thereof. I. In aspects, the second layer 1520 can comprise a plurality of layers of such inorganic materials. In some aspects, such layers of inorganic materials can form an optical stack to impart a desired optical functionality to the underside stack. For example, the plurality of layers of inorganic materials can be used to provide an anti-reflective (AR) coating, a band-pass filter coating, an edge neutral mirror, a beam splitter coating, a multi-layer high-reflectance coating, and/or an edge filter coating. Such an optical stack could be implemented as any of the structures described in U.S. Pat. No. 9,328,016, issued May 3, 2016, U.S. Pat. No. 9,684,097, issued Jun. 20, 2017, U.S. Pat. No. 9,703,011, issued Jul. 11, 2017, U.S. Pat. No. 9,079,802, issued Jul. 14, 2015, U.S. Pat. No. 9,726,786, issued Aug. 8, 2017, U.S. Pat. No. 10,416,352, issued Sep. 17, 2019, which are incorporated by reference in their entirety. For example, such a stack could be an anti-reflective coating and/or a scratch-resistant coating. However, depending on the positioning of the underside optical stack in the incorporating device (e.g., the foldable device 1100 described herein with respect to FIG. 11), the optical properties of the composite article 1500 may not be important. Such implementations may be beneficial in that they may allow maximum flexibility in terms of the inorganic material(s) that may be used to construct the second layer 1520.

In aspects, the second layer 1520 is formed of an inorganic material exhibiting a refractive index that is higher than that of the glass-based layer 1510. Exemplary materials include SiᵤAlᵥOₓN_{y}, AlN, oxygen-doped SiNₓ, SiNₓ, Si₃N₄, AlOₓN_{y}, SiOₓN_{y}, Ta₂O₅, Nb₂O₅, HfO₂, TiO₂, ZrO₂, Y₂O₃, ZrO₂, Al₂O₃, and diamond-like carbon. Such materials can also beneficially provide higher a thermal conductivity than the glass-based materials described herein (e.g., to facilitate the second glass-based layer functioning as a heat sink layer). In preferred aspects, the second layer 1520 can comprise (or consist) of an oxynitride (e.g., SiOₓN_{y}). The oxygen content of the materials for the second layer 1520 may be minimized, especially in SiNₓ or AlNₓ materials. The foregoing materials may be hydrogenated up to 30% by weight. As used herein, it is to be understood that the subscripts (e.g., “u,” “v”, “x,” “y,” and “z”) range from greater than 0 to 1, where the subscripts sum to 1 to represent an “atomic fraction formula.” See, for example: (i) Charles Kittel, Introduction to Solid State Physics, seventh edition, John Wiley & Sons, Inc., NY, 1996, pp. 611-627; (ii) Smart and Moore, Solid State Chemistry, An introduction, Chapman & Hall University and Professional Division, London, 1992, pp. 136-151; and (iii) James F. Shackelford, Introduction to Materials Science for Engineers, Sixth Edition, Pearson Prentice Hall, New Jersey, 2005, pp. 404-418. The balance of the material (i.e., 1 minus the sum of the subscripts) is the first atom (e.g., SiNₓ with x=0.57 actually corresponds to Si_{0.43} N_{0.57}, which is the same as Si₃N₄). Also, the sum of all subscripts is greater than 0.

In aspects, the second layer 1520 can be deposited onto the glass-based layer 1510 (directly deposited with no using various deposition methods, for example, vacuum deposition techniques, chemical vapor deposition (e.g., plasma enhanced chemical vapor deposition (PECVD), low-pressure chemical vapor deposition, atmospheric pressure chemical vapor deposition, and plasma-enhanced atmospheric pressure chemical vapor deposition), physical vapor deposition (e.g., reactive or nonreactive sputtering or laser ablation), thermal or e-beam evaporation and/or atomic layer deposition. Liquid-based methods may also be used, for example, printing, spraying, or slot coating. In aspects, the vacuum deposition can be made by a linear PECVD source. In aspects, second layer 1520 can be prepared using a sputtering process (e.g., a reactive sputtering process), chemical vapor deposition (CVD) process, plasma-enhanced chemical vapor deposition process, or some combination of these processes. In aspects, the second layer 1520 can be prepared according to a reactive sputtering process. In aspects, hard coating can be fabricated using a metal-mode, reactive sputtering in a rotary drum coater.

The second layer comprises a first major surface 1522, a second major surface 1524, and a thickness 1526 extending between the first major surface 1522 and the second major surface 1524. In aspects, the thickness 1526 can be 0.1 μm or more, 0.3 μm or more, 0.5 μm or more, 0.7 μm or more, 1 μm or more, 10 μm or less, 5 μm or less, 2 μm or less, or 1 μm or less. For example, the thickness 1526 can be 0.1 μm, 0.2 μm, 0.3 μm, 0.4 μm, 0.5 μm, 0.6 μm, 0.7 μm, 0.8 μm, 0.9 μm, 1 μm, 1.5 μm, 2 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm, 9.5 μm, 10 μm, or any thickness lying in any range bounded by any two of the preceding values inclusive endpoints (e.g., from 1 μm to 10 μm, from 2 μm to 5 μm, etc.). In aspects, the thickness 1526 can be greater than or equal to 1.5% of the thickness 1516 and less than or equal to 100% of the substrate thickness. For example, in aspects, the thickness 1526, expressed as a percentage of the thickness 1516, can be 1.5%, 2.0%, 2.5%, 3.0%, 3.5%, 4.0%, 4.5%, 5.0%, 5.5%, 6.0%, 6.5%, 7.0%, 7.5%, 8.0%, 8.5%, 9.0%, 9.5%, 10.0%, 10.5%, 11.0%, 11.5%, 12.0%, 12.5%, 13.0%, 13.5%, 14.0%, 14.5%, 15.0%, 15.5%, 16.0%, 16.5%, 17.0%, 17.5%, 18.0%, 18.5%, 19.0%, 19.5%, 20.0%, 20%, 25%, 30%, 35%, 40%, 45%, 50%, 55%, 60%, 65%, 70%, 75%, 80%, 85%, 90%, 95%, 100%, or any percentage lying in any range defined by any two of the preceding values as inclusive endpoints (e.g., from 1.5% to 100%, from 2% to 100%, from 3% to 20%, from 10% to 15%, from 8% to 12%, from 1.5% to 3.0%, from 20% to 30%, etc.).

In aspects, an elastic modulus (e.g., Young's modulus) of the second layer 1520 is determined using nanoindentation with a Berkovich diamond indenter tip. See: Fischer-Cripps, A. C., “Critical Review of Analysis and Interpretation of Nanoindentation Test Data,” Surface & Coatings Technology, 200, 4153-4165 (2006); and Hay, J., Agee, P, and Herbert, E., “Continuous Stiffness measurement During Instrumented Indentation Testing, Experimental Techniques,” 34 (3) 86-94 (2010). For coatings, instantaneous estimates of the elastic modulus are measured as a function of indentation depth. The elastic modulus is taken as the maximum value of the instantaneous estimate of the elastic modulus for measurements within the thickness 1526 minus 5 nm from the corresponding exterior surface. Without wishing to be bound by theory, if a coating is of sufficient thickness, then it is then possible to isolate the properties of the coating from an adjacent coating based on the resulting response profiles as a function of depth. Extraction of reliable nanoindentation data is based on well-established protocols described in the above-mentioned references. In aspects, an elastic modulus of the second layer 1502 can be 100 GPa or more, 120 GPa or more, 150 GPa or more, 170 GPa or more, 200 GPa or more, 220 GPa or more, 300 GPa or less, 250 GPa or less, 220 GPa or less, 210 GPa or less, 200 GPa or less, 180 GPa or less, 160 GPa or less, 140 GPa or less, or 120 GPa or less. In aspects, an elastic modulus the second layer 1520 can be from 100 GPa to 300 GPa, from 120 GPa to 250 GPa, from 150 GPa to 220 GPa, from 170 GPa to 200 GPa, or any range or subrange therebetween. In aspects, the elastic modulus of the second layer 1520 can be at least 10 GPa greater than that of the glass-based layer 1510. For example, a difference between the elastic modulus of the second layer 1520 and that of the glass-based layer 1510 can be 10 GPa, 20 GPa, 30 GPa, 40 GPa, 50 GPa, 60 GPa, 70 GPa, 80 GPa, 90 GPa, 100 GPa, 110 GPa, 120 GPa, 130 GPa, 140 GPa, 150 GPa, or any value lying in any range bounded by any of two of the preceding values as inclusive endpoints (e.g., from 30 GPa to 80 GPa, from 50 GPa to 70 GPa, etc). Such a large modulus contrast facilitates achieving a higher stiffness at relatively lower thickness than if the second glass-based layer were formed of glass-based material alone.

A variety of configurations for the composite article are contemplated and within the scope of the present disclosure. FIG. 15 depicts an embodiment in which the second layer 1520 comprises a uniform thickness and covers an entirety of the second major surface of the glass-based layer 1510. In such an implementation, the composite article 1500 could either be oriented so that the second layer 1520 faces the cover glass stack 200 (i.e., so that the second layer 1520 is positioned between the glass-based layer 1510 and the cover glass stack 200), or with the second layer 1520 facing away from the cover glass stack 200 (i.e., so that glass-based layer 1510 is more proximate to the display substrate 304). It is believed that implementations where the second layer 1520 is facing away from the cover glass stack 200 are beneficial in that it facilitates shifting a neutral axis 150 (see FIG. 2A) towards a center of the display panel 300, thereby lowering tensile strains.

The properties of the second layer 1520 can be tunable via the method used to deposit the second layer 1520 on the glass-based layer 1510. For example, in embodiments where the second layer 1520 is formed of a silicon nitride material, a reaction to nitride or oxynitride in an inductively coupled plasma (ICP) region within a sputtering chamber can be used. In such a process, parameters to control include: number of targets used, power applied to each sputtering target (kW), deposition time for each layer, and ICP power. Gas flow rates can also be used to control layer characteristics. For example, argon (Ar) gas flows at the sputtering target (sccm) can used to control the residual stresses in the second layer 1520. O₂ and N₂ flow rates were used to tune the refractive index, modulus, and extinction coefficient of each layer. In an example, the following parameters can be used to deposit the second layer as a SiON layer: four sputtering targets; the power applied to each sputtering target: <9 kW; Ar flow rates for each target: 150 to 500 sccm were used for each target; ICP power beneath 3 kW; N₂ gas flow in the ICP region: between 200 and 250 sccm; O₂ flow in the ICP region: less than 15 sccm.

In aspects, the residual stresses present in the second layer 1520, combined with the orientation of the composite article 1500, can be used to improve functionality of the foldable apparatus 10. For example, the residual stresses in the second layer 1520 can be used to assist bending by orienting the composite article 1500 so that it tends to bend toward the cover glass stack 200 (e.g., if compressive stresses are present in the second layer 1520 and the composite article 1500 is oriented with the second layer 1520 away from the cover glass stack 200). Such a configuration could lower the amount of bending force required to reconfigure the foldable device 1100 between the open and closed configurations described herein with respect to FIG. 11. Alternatively, an opposite orientation (assuming the same residual compressive stress) allows the residual stresses provided by the second layer 1520 to counteract creasing (e.g., by orienting the composite article 1500 so that the composite article 1500 tends to bend away from the cover glass stack 200).

In aspects, the second layer 1520 can comprise a residual stress of less than +200 MPa (tensile) to −1100 MPa (compression). For example, the residual stress can be 200 MPa, 150 MPa, 100 MPa, 50 MPa, 0 MPa, −50 MPa, −100 MPa, −150 MPa, −200 MPa, −250 MPa, −300 MPa, −350 MPa, −400 MPa, −450 MPa, −500 MPa, −550 MPa, −600 MPa, −650 MPa, −700 MPa, −750 MPa, −800 MPa, −850 MPa, −900 MPa, −950 MPa, −1000 MPa, −1050 MPa, −1100 MPa, or any value lying in any range bounded by any two of the preceding values as inclusive endpoints. Unless otherwise noted, residual stress in the second layer 1520 is obtained by measuring the curvature of the composite article 1500 before and after deposition of the second layer 1520 and then calculating residual film stress according to the Stoney equation according to principles known and understood by those with ordinary skill in the field of the disclosure. In aspects, if undesired, such residual compressive stress in the second layer 1520 can be counteracted by performing an asymmetric ion exchange strengthening of the glass-based layer 1510 (e.g. so that the major surface of the glass-based layer 1510 not covered by the second layer 1520 exhibits at least one of a greater depth of compression or surface compressive stress than the major surface covered by the second layer 1520). Such asymmetric ion exchange can be performed by the methods described in U.S. Pat. No. 10,752,542 B2, entitled “Asymmetric Stress Profiles for Low Warp and High Damage Resistance Glass Articles,” hereby incorporated by reference in its entirety.

In aspects, the thickness 1526 of the second layer 1520 may not be uniform. For example, portions of the second layer 1520 that are at least 5 mm from the bend axis 102 (see FIG. 2A) could have a greater thickness than the portion of the second layer 1502 within 5 mm of the bend axis. Such a configuration could beneficially aid the un-bent portions of the foldable apparatus retaining their shape when the incorporating device is folded and unfolded.

In aspects, the glass-based layer 1510 can take the form of the second glass-based layer 402′ depicted in FIG. 2B. In such aspects, the second layer 1502 could be disposed only in the cavity defined by the recessed major surface (i.e., in place of the polymer portion 426 depicted in FIG. 2C). Such a configuration adds stiffness to the area overlapping the bend axis 102 to improve crease recovery performance while minimally impacting overall bend force needed to fold the apparatus. In alternative aspects, the second layer 1520 could be deposited only the portions of the first major surface 410 that are outside of the cavity (not in the recess). Such a configuration could add stiffness to the portions of the foldable apparatus 10 that are not desired to change in chape during bending. In the embodiments depicted in FIGS. 2C and 2D each separate segment of the second glass-based layers 402″ and 402′″ could be replaced by a composite article 1500 depicted in FIG. 15.

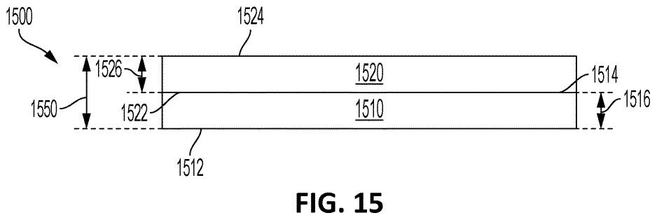

In aspects, the second layer 1520 can be segmented into a plurality of separate components. For example, FIG. 16 depicts a composite article 1500′ comprising the glass-based layer 1510 described herein with respect to FIG. 15 and a second layer 1520′ that is broken up into segments 1520a, 1520b, 1520b that are separated from one another so that the glass-based layer 1510 comprises uncovered portions 1700, 1710 that do not have any material of the second layer 1520′ adhered thereto. The numbering and positioning of the segments 1520a, 1520b, 1520b can vary depending on the implementation. For example, with reference to FIG. 11, the uncovered portions 1700, 1710 can overlap with the transition region 1113 where it is desired that some level of bending take place in the foldable apparatus 10. Such decreased rigidity of the foldable apparatus 10 in precise location can facilitate the foldable apparatus 10 bending to a desired geometry when the foldable device 1100 is folded from the open configuration to the closed configuration with minimal impact on bending force required to close the foldable device 1100. In an alternative embodiment, the segments 1520a, 1520b, 1520b can be positioned in areas where the foldable apparatus 10 is expected to be bent to the greatest degree (e.g., so as to overlap the transition region 1113) to facilitate crease recovery performance. The geometry, number, and arrangement of the segments 1520a, 1520b, 1520b can vary depending on the implementation. While completely separate segments are depicted in FIG. 16, the second layer 1520′ could be deposited in a different pattern (e.g., where segments have different shapes and/or are connected to one another).

With reference to FIG. 2A, it is contemplated that the second glass-based layer 402 (or any of the other second-glass-based layers in the embodiments described with respect to FIGS. 2B-2D) can comprise a laminate with multiple layers of glass-based material (e.g., two layers of glass-based material, three layers of glass-based material, four layers of glass-based material, or an even greater number of layers of glass-based material). Each layer of glass-based material in the laminate can individually comprise a thickness lying within any of the ranges for the first thickness 214 of the first glass-based layer 202 described herein and be formed of the materials described herein with respect to the first and second glass-based layers 202 and 402. When the second glass-based layer 402 is implemented as a laminate, the layers of glass-based material can be attached to one another via a suitable adhesive. In embodiments, the adhesive is one of the materials described herein with respect to the layers of optically clear adhesive 206. It is believed that splitting the second glass-based layer 402 into multiple layers (with intervening adhesives) can further add to the elastic response of the foldable apparatus 10 for a given total amount of glass thickness in the second glass-based layer 402 via placement of the neutral axis 150. More glass-based material further away from the rear surface 307 can add elasticity to the foldable apparatus. Using a laminate structure for the second glass-based layer 402 can improve the elastic response without adding additional glass-based material. It is believed that this can improve creasing performance (e.g., from an initial crease height perspective after being held in the bent state) of the foldable apparatus 10. As described in greater detail herein adding glass-based material to the underside stack 400 by implementing the second glass-based layer 402 as a laminate can provide improvements in creasing performance. Such benefits can be provided without degrading bending performance (e.g., in terms of increased bending-induced stress on the second glass-based layer 402 and increased bending force) to as much of an extent as the case where glass-based material is simply added by providing a single layer of glass-based material with a greater thickness). Adding glass-based material by making a single glass-based layer thicker adds greater amounts of stresses and adds to the force required to fold the foldable apparatus 10 to a greater extent.

In aspects, when the second glass-based layer 402 is implemented as a laminate with two or more glass-based layers attached to one another by a layer of optically clear adhesive, a combined thickness of the glass-based layers in the laminate may be greater than or equal to the first thickness 214. When the glass-based layers in the second glass-based layer 402 are formed of a glass-based material having the same composition as the first glass-based layer 202, it is believed that having the combined thickness be greater than or equal to the first thickness 214 can be particularly beneficial in that it ensures elasticity is added to aid in improving crease performance. In aspects, when the glass-based layers in the second glass-based layer 402 are formed of a glass-based material having the same composition as the first glass-based layer 202, a combined thickness of the glass-based layers in the second glass-based layer 402 can be at least 10 μm greater than the first thickness 214. For example, the combined thickness of the glass-based layers in the second glass-based layer 402 can be 10 μm, 15 μm, 20 μm, 25 μm, 30 μm, 35 μm, 40 μm, 45 μm, 50 μm, 55 μm, 60 μm, 65 μm, or even 70 μm greater than the first thickness 214, or any thickness difference lying in any range bounded by any two of the preceding values as inclusive endpoints (e.g., from 10 μm to 30 μm, from 50 μm to 70 μm, etc.). Such a thickness difference ensures elasticity to counteract creasing, when the first and second glass-based layers 202 and 402 are formed of the same glass-based material.

In embodiments, each of the layers of glass-based material in the second glass-based layer 402 can comprise the same thickness. Alternatively, the thickness of at least one glass-based layer in the second glass-based layer 402 can be different than that of the others. For example, in aspects, the glass-based layer that is most proximate to the display panel 300 can have a thickness that is greater than that of the other glass-based layers in the laminate. The thicknesses of the glass-based layers in the laminate can decrease with increasing distance from the display panel 300 to add elasticity without adding as much bend force as the case where all the glass-based layers in the laminate had the same thickness as the layer closest to the display panel.

In aspects, when the second glass-based layer 402 is implemented as a laminate, each glass-based layer in the laminate can be formed of the same glass-based material. Alternatively, the layers of glass-based material can be formed of different glass-based materials. In an example, the layer most proximate to the display panel 300 can be formed of a glass-based material exhibiting a higher elastic modulus than that of another glass-based layer further from the display panel 300 (e.g., the layer most proximate the display panel 300 can be formed of a glass-ceramic while another layer can be formed of an amorphous glass material). Alternatively, or additionally, the layers in laminate can be ion-exchanged to a different extent. For example, in aspects, a layer most proximate to the display panel 300 may be ion-exchanged to exhibit compressive stress regions as described herein with respect to the first glass-based layer 202, while another glass-based layer may not be ion exchanged.

Examples 7 and 8 were modelled to determine creasing performance when bent to the waterdrop configuration described with respect to FIGS. 13A and 13B. Example 7 had the structure provided in Table 4. Example 8 had the structure provided in Table 5. The layers were assumed to have the properties in Table 2.

TABLE 4
Example 7 Structure

| Layer | Thickness (μm) |
|---|---|
| CBG | 38 |
| OCA | 64 |
| Polarizer | 31 |
| Touch Pad | 25 |
| TFE | 16 |
| AMOLED | 22 |
| CBG | 25 |
| OCA | 10 |
| CBG | 25 |

TABLE 5
Example 8 Structure

| Layer | Thickness (μm) |
|---|---|
| CBG | 38 |
| OCA | 64 |
| Polarizer | 31 |
| Touch Pad | 25 |
| TFE | 16 |
| AMOLED | 22 |
| CBG | 50 |
| OCA | 10 |
| CBG | 40 |

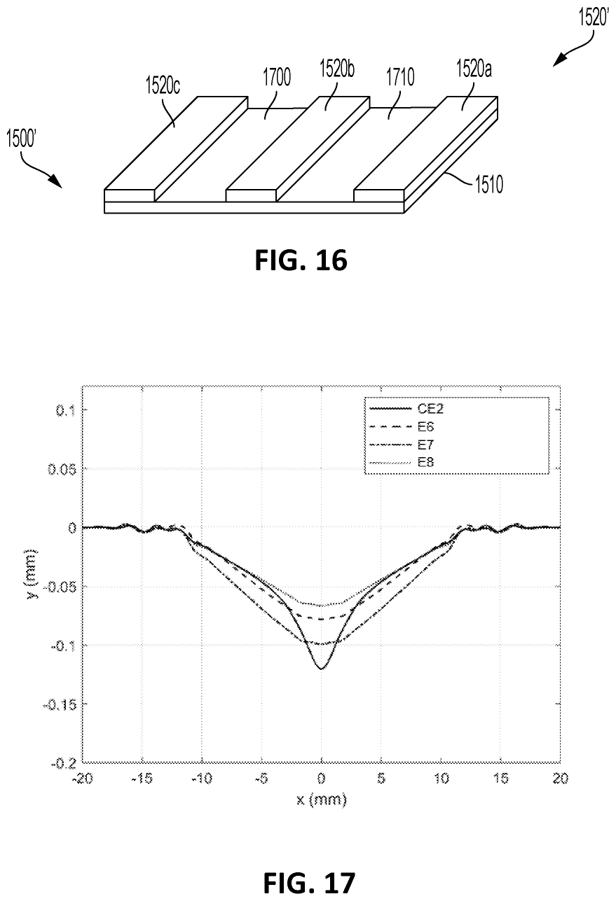

As shown, Example 7 differed from Example 6 shown in FIG. 12B in that the second glass-based layer was replaced by a laminate having the same total glass thickness, with the second glass-based layer in Example 6 being split between two layers having the same thickness. Example 8 differed from Example 6 in that an additional 40 μm layer of glass-based material was added to the stack. Examples 7 and 8 were modelled for creasing performance as described herein with respect to FIGS. 13A-13B. FIG. 17 plots the results of a predicted shape of the front surfaces 4 seconds after release (the results of Counter Example 2 and Example 6 are also provided for comparison). In terms of optical distortion, Counter Example 2 was predicted to exhibit 36.1 D, Example 2 was predicted to exhibit 16.5 D, Example 7 was predicted to exhibit 21.1 D, and Example 8 was predicted to exhibit 16.2 D. Example 8 was predicted to exhibit an initial crease height that was about 50% of that exhibited by Counter Example 2. These results demonstrate that adding additional layers of glass-based material to the underside stack 400 can further improve creasing performance.

Directional terms as used herein—for example, up, down, right, left, front, back, top, bottom—are made only with reference to the figures as drawn and are not intended to imply absolute orientation.

It will be appreciated that the various disclosed embodiments may involve features, elements, or steps that are described in connection with that embodiment. It will also be appreciated that a feature, element, or step, although described in relation to one embodiment, may be interchanged or combined with alternate embodiments in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises embodiments having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, embodiments include from the one particular value and/or to the other particular value. Similarly, when values are expressed as approximations, by use of the antecedent “about,” it will be understood that the particular value forms another embodiment. Whether or not a numerical value or endpoint of a range in the specification recites “about,” the numerical value or endpoint of a range is intended to include two embodiments: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In some embodiments, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to an apparatus that comprises A+B+C include embodiments where an apparatus consists of A+B+C and embodiments where an apparatus consists essentially of A+B+C. As used herein, the terms “comprising” and “including”, and variations thereof shall be construed as synonymous and open-ended unless otherwise indicated.

The above embodiments, and the features of those embodiments, are exemplary and can be provided alone or in any combination with any one or more features of other embodiments provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the embodiments herein provided they come within the scope of the appended claims and their equivalents.

What is claimed is:

1. A foldable apparatus comprising:
a cover glass stack comprising a first glass-based layer, the first glass-based layer comprising a first thickness that is greater than or equal to 10 μm and less than or equal to 200 μm;
an OLED display panel disposed on the cover glass stack, the OLED display panel comprising a display substrate; and
a second glass-based layer disposed on the OLED display panel such that the display substrate is disposed between the first glass-based layer and the second glass-based layer, the second glass-based layer comprising a second thickness that is greater than or equal to 10 μm and less than or equal to 200 μm, wherein:
the cover glass stack is protective cover for the OLED display panel so that an image generated by the display is viewable through the cover glass stack,
the foldable apparatus is configured to bend at a bend axis,
when the foldable apparatus is maintained in a bent state for a time period of at least 24 hours so that a front surface of foldable apparatus exhibits a minimum bend radius of less than 20 mm and subsequently released, the foldable apparatus comprises a crease region,
the second glass-based layer comprises a continuous volume of glass-based material with a minimum thickness of at least 10 μm within the crease region,
a combined thickness of the first and second glass-based layers is greater than or equal to 30 μm, and
at least one of:
a first major surface of the second glass-based layer is disposed within 400 μm of a rear surface of the display substrate,
the second glass-based layer comprises a plurality of segments that are separated from one another by gaps so that the second glass-based layer does not cover an entirety of the display substrate,
the second glass-based layer comprises a variable thickness component of glass-based material,
the second glass-based layer is a component of a laminate, the laminate comprising an additional layer of glass-based material laminated to the second glass-based layer, and
the foldable apparatus, when maintained at a parallel plate distance of 3 mm, exhibits a maximum tensile strain in the OLED display panel that is less than a comparative foldable apparatus having the same structure as the foldable apparatus except the comparative foldable apparatus has the second glass-based layer removed.

2. The foldable apparatus of claim 1, wherein the second glass-based layer comprises the variable thickness component and the variable thickness component is the second glass-based layer, which comprises a reduced-thickness portion, wherein the reduced thickness portion is centered at the bend axis.

3. The foldable apparatus of claim 1, wherein:
the second glass-based layer comprises the plurality of segments, and
the plurality of segments comprise a central segment centered on the bend axis and two or more off-center segments offset from the central segment away from the bend axis.

4. The foldable apparatus of claim 3, wherein the central segment comprises a width in a direction perpendicular to the bend axis that is greater than widths of the off-center segments.

5. The foldable apparatus of claim 1, wherein the second glass-based layer has a total thickness of glass-based material that is greater than that of the first glass-based layer.

6. The foldable apparatus of claim 1, wherein a Young's modulus of the second glass-based layer is at least 5 GPa greater than a Young's modulus of the first glass-based layer.

7. The foldable apparatus of any claim 1, wherein the second glass-based layer comprises a thermal conductivity greater than or equal to 0.05 W*m⁻¹*K⁻¹.

8. The foldable apparatus of claim 1, wherein:
both the first glass-based layer and the second glass-based layer are ion exchanged so that they have regions of compressive stress extending inward from major surfaces thereof,
each of the first glass-based layer and the second glass-based layer consists of a single layer of glass-based material, and
at least one of:
the first glass-based layer exhibits a greater maximum compressive stress (CS) than that of the second glass-based layer, and
the first glass-based layer exhibits a ratio of CS (in MPa) to Young's modulus (in GPa) that is at least 1.0 (units omitted) greater than that of the second glass-based layer.

9. The foldable apparatus of claim 1, wherein:
the parallel plate distance occurs when the foldable apparatus is bent in an elliptical bend configuration,
a fold plane extending perpendicular to the bend axis and perpendicular to at least a portion of a major surface of the first glass-based layer when the foldable apparatus is in an unbent state extends through glass-based material of the second glass-based layer, and
after being held at the parallel plate distance for a period of 120 hours and subsequently released, a front surface of the foldable apparatus exhibits a crease height recovery of at least 40% over a 24-hour period after being released.

10. The foldable apparatus of claim 1, wherein, when the foldable apparatus is folded in a waterdrop configuration such that unbent portions of the foldable apparatus are separated by a minimum separation distance of 1.3 mm and the foldable apparatus is maintained in the waterdrop configuration for 24 hours and subsequently released, the foldable apparatus exhibits an initial maximum optical distortion of less than 30 D when viewed from a front surface of the foldable apparatus 2 minutes after release.

11. The foldable apparatus of claim 10, wherein, 24 hours after release, the foldable apparatus exhibits a second maximum optical distortion value that is less than 50% of the initial maximum optical distortion value.

12. The foldable apparatus of claim 1, wherein the second glass-based layer comprises a composite article, the composite article comprising:
a glass-based layer formed of a glass-based material; and
a second layer disposed directly on the glass-based layer, the second layer comprising an elastic modulus that is at least 10 GPa greater than the glass-based layer, wherein the second layer comprises a thickness that is greater than or equal to 1 μm and less than or equal to 10 μm.

13. The foldable apparatus of claim 12, wherein the thickness of the second layer is at least 2.0% of a thickness of the glass-based layer.

14. The foldable apparatus of claim 13, wherein the second layer comprises Al₂O₃, AlN, AlOₓN_{y}, Si₃N₄, SiOₓN_{y}, SiᵤAlᵥOₓN_{y}, diamond, diamond-like carbon, SiₓC_{y}, SiₓO_{y}C_{z}, ZrO₂, TiOₓN_{y}, or combinations thereof.

15. The foldable apparatus of claim 13, wherein the second layer comprises a residual stress of less than +200 MPa (tensile) to −1100 MPa (compressive).

16. The foldable apparatus of claim 1, wherein:
the second glass-based layer is a component of the laminate,
a glass-based layer of the laminate most proximate to the OLED display panel exhibits at least one of: (a) a greatest thickness of all the glass-based layers in the laminate and; (b) a greatest elastic modulus of all the glass-based layers in the laminate.

17. A foldable apparatus comprising:
a cover glass stack comprising a first glass-based layer, the first glass-based layer comprising a first thickness that is greater than or equal to 10 μm and less than or equal to 200 μm;
an OLED display panel disposed on the cover glass stack, the OLED display panel comprising a display substrate; and
a second glass-based layer disposed on the OLED display panel such that the display substrate is disposed between the first glass-based layer and the second glass-based layer, the second glass-based layer comprising a second thickness that is greater than or equal to 10 μm and less than or equal to 100 μm, wherein:
the cover glass stack is protective cover for the OLED display panel so that an image generated by the display is viewable through the cover glass stack,
the foldable apparatus is configured to bend at a bend axis,
a combined thickness of the first and second glass-based layers is greater than or equal to 30 μm,
a fold plane containing the bend axis and extending perpendicular to at least a portion of a major surface of the first glass-based layer when the foldable apparatus is in an unbent state extends through glass-based material of the second glass-based layer, and
when the foldable apparatus is either (a) held in a state to exhibit a parallel plate distance of 3.0 mm for 120 hours; or (b) held with a waterdrop bend geometry with a minimum separation distance of 1.3 mm for 24 hours and subsequently released, a front surface of the foldable apparatus exhibits a crease height recovery of at least 40% over the 24 hour period after release.

18. The foldable apparatus of claim 17, wherein at least one of:
the second glass-based layer comprises a plurality of segments that are separated from one another by gaps so that the second glass-based layer does not cover an entirety of the display substrate,
the second glass-based layer comprises a variable thickness component of glass-based material
the second glass-based layer is a component of a laminate, the laminate comprising an additional layer of glass-based material laminated to the second glass-based layer, and
the second glass-based layer comprises a composite article, the composite article comprising:
a glass-based layer formed of a glass-based material; and
a second layer disposed directly on the glass-based layer, the second layer comprising an elastic modulus that is at least 10 GPa greater than the glass-based layer.

19. The foldable apparatus of claim 18, wherein:
the second glass-based layer is a component of the laminate,
a glass-based layer of the laminate most proximate to the OLED display panel exhibits at least one of: (a) a greatest thickness of all the glass-based layers in the laminate and; (b) a greatest elastic modulus of all the glass-based layers in the laminate.

20. The foldable apparatus of claim 17, wherein a Young's modulus of the second glass-based layer is at least 5 GPa greater than a Young's modulus of the first glass-based layer.
